(19) United States
(12) Patent Application Publication
(10) Pub. No.: US 2026/0223619 A1
(43) Pub. Date: Jul. 30, 2026

(54) SUBSTRATE PROCESSING METHOD

(71) Applicant: SCREEN Holdings Co., Ltd., Kyoto (JP)

(72) Inventors: Yuta NISHIMURA, Kyoto-shi, Kyoto (JP); Taichi NISHIMORI, Kyoto-shi, Kyoto (JP); Taiki HINODE, Kyoto-shi, Kyoto (JP)

(21) Appl. No.: 19/139,867

(22) PCT Filed: Nov. 10, 2023
(86) PCT No.: PCT/JP2023/040526

§ 371 Date: Jun. 16, 2025

(30) Foreign Application Priority Data
Dec. 23, 2022 (JP) 2022-206478
Jul. 27, 2023 (JP) 2023-122394

(51) Int. Cl. H10P 70/00; H10P 72/00

(52) U.S. Cl. CPC H10P 70/20; H10P 72/0414

(57) ABSTRACT

A substrate processing method includes holding a substrate having a plurality of dies on a main surface, supplying a rinse liquid to the main surface of the substrate while the substrate is rotated at a rotation speed at which the rinse liquid covers the plurality of dies, after supplying the rinse liquid, and supplying the chemical liquid from a first nozzle toward the main surface of the substrate while the substrate is rotated at a rotation speed at which the chemical liquid covers the plurality of dies.

### CROSS-REFERENCE TO RELATED APPLICATIONS

The present application is a 35 U.S.C. §§ 371 national phase conversion of International Application No. PCT/JP2023/040526, filed Nov. 10, 2023, which claims priority to Japanese Patent Application Nos. 2022-206478, filed Dec. 23, 2022 and 2023-122394, filed Jul. 27, 2023, the entire contents of which are incorporated herein by reference. The PCT International Application was published in the Japanese language.

### TECHNICAL FIELD

The present disclosure relates to a substrate processing method.

### BACKGROUND ART

Conventionally, a substrate processing apparatus that supplies a processing liquid to a substrate to process the substrate has been proposed (for example, Patent Document 1). According to Patent Document 1, a substrate processing apparatus includes a spin chuck, a first chemical liquid nozzle, a second chemical liquid nozzle, and a rinse liquid nozzle. The spin chuck rotates the substrate around a vertical rotation axis passing through the center of the substrate while holding the substrate in a horizontal posture. The first chemical liquid nozzle is a shower nozzle. The first chemical liquid nozzle and the second chemical liquid nozzle dispense a chemical liquid in parallel toward the upper surface of the rotating substrate. Since the chemical liquid spreads on the upper surface of the substrate, the chemical liquid acts on the entire upper surface of the substrate. Next, the rinse liquid nozzle dispenses a rinse liquid toward the upper surface of the rotating substrate. Thus, the chemical liquid on the upper surface of the substrate is washed away by the rinse liquid.

### PRIOR ART DOCUMENT

### Patent Document

Patent Document 1: Japanese Patent Application Laid-Open No. 2018-195738

### SUMMARY

### Problem to be Solved by the Invention

There is a case where a substrate including a support substrate and a plurality of dies attached to a main surface of the support substrate is processed. Since the thickness of the die is larger than the thickness of the pattern, relatively deep irregularities are formed on the main surface of the substrate. Therefore, when the chemical liquid is dispensed toward the main surface of the substrate, liquid splashing may occur due to irregularities, or the flow of the chemical liquid on the main surface of the substrate may become uneven due to irregularities. Due to these factors, on the main surface of the substrate, a position where the chemical liquid reaches relatively quickly and a position where the chemical liquid reaches relatively slowly become apparent. That is, the chemical liquid starts to act at different start timings at each position on the main surface of the substrate. Thus, uniformity of processing on the substrate is deteriorated.

Therefore, an object of the present disclosure is to provide a technique capable of starting to cause the chemical liquid to act more uniformly on the main surface of the substrate.

### Means to Solve the Problem

A first aspect is a substrate processing method including: holding a substrate having a plurality of dies on a main surface; supplying a rinse liquid to the main surface of the substrate while rotating the substrate at a rotation speed at which the rinse liquid covers the plurality of dies; and supplying a chemical liquid from a first nozzle toward the main surface of the substrate while rotating the substrate at a rotation speed at which the chemical liquid covers the plurality of dies after supplying the rinse liquid.

A second aspect is the substrate processing method according to the first aspect, wherein the substrate is held in a posture in which the main surface is directed upward, a liquid film of the rinse liquid covering the plurality of dies is maintained on the main surface of the substrate in supplying the rinse liquid, and a liquid film of the chemical liquid covering the plurality of dies is maintained on the main surface of the substrate in supplying the chemical liquid.

A third aspect is the substrate processing method according to the second aspect, wherein in supplying the chemical liquid, the chemical liquid is dispensed from a plurality of dispense ports toward the main surface of the substrate while reciprocating the first nozzle having the plurality of dispense ports in a direction along the main surface of the substrate.

A fourth aspect is the substrate processing method according to the second or the third aspect, wherein in supplying the chemical liquid, the chemical liquid is continuously dispensed from the first nozzle even after replacing the rinse liquid on the main surface of the substrate with the chemical liquid for an actual processing time longer than a replacement time required for replacing the rinse liquid with the chemical liquid.

A fifth aspect is the substrate processing method according to any one of the second aspect to the fourth aspect, wherein a difference between a chemical liquid processing time for dispensing the chemical liquid from the first nozzle toward the main surface of the substrate and an integral multiple of a unit time required for one rotation of the substrate is ¼ or less of the unit time.

A sixth aspect is the substrate processing method according to any one of the second aspect to the fifth aspect, wherein in supplying the rinse liquid, the rinse liquid is dispensed from the first nozzle toward the main surface of the substrate.

A seventh aspect is the substrate processing method according to any one of the second aspect to the sixth aspect, further including: dispensing the rinse liquid from the first nozzle toward the main surface of the substrate while rotating the substrate at a rotation speed at which the rinse liquid covers the plurality of dies after supplying the chemical liquid.

An eighth aspect is the substrate processing method according to the seventh aspect, wherein a difference between a rotation speed of the substrate in supplying the chemical liquid and a rotation speed of the substrate in supplying the rinse liquid after supplying the chemical liquid is 50% or less of the rotation speed of the substrate in supplying the chemical liquid.

A ninth aspect is the substrate processing method according to the seventh or the eighth aspect, further including: supplying the rinse liquid to the main surface of the substrate while rotating the substrate at a first rotation speed higher than a second rotation speed of the substrate in supplying the rinse liquid after supplying the chemical liquid, after supplying the rinse liquid and supplying the chemical liquid.

A tenth aspect is the substrate processing method according to the ninth aspect, wherein in supplying the rinse liquid while rotating the substrate at the first rotation speed, the rinse liquid is dispensed from a second nozzle toward a central portion of the main surface of the substrate.

An eleventh aspect is the substrate processing method according to the ninth or the tenth aspect, further including: drying the substrate by rotating the substrate at a third rotation speed higher than the first rotation speed after supplying the rinse liquid while rotating the substrate at the first rotation speed.

A twelfth aspect is the substrate processing method according to any one of the ninth aspect to the eleventh aspect, wherein one set of supplying the rinse liquid before supplying the chemical liquid, supplying the chemical liquid, supplying the rinse liquid while rotating at the second rotation speed, and supplying the rinse liquid while rotating at the first rotation speed is performed a plurality of times, and in supplying the chemical liquid, different chemical liquids are supplied to the main surface of the substrate.

A thirteenth aspect is the substrate processing method according to the first aspect, wherein the substrate is held in a posture with the main surface facing downward.

A fourteenth aspect is the substrate processing method according to the thirteenth aspect, wherein in supplying the chemical liquid, the chemical liquid is dispensed from a plurality of dispense ports of the first nozzle toward the main surface of the substrate, and the first nozzle dispenses the chemical liquid toward a peripheral region of the main surface at a flow rate larger than a flow rate to a central region of the main surface of the substrate, the peripheral region being radially outward from the central region.

A fifteenth aspect is the substrate processing method according to the first aspect, wherein in supplying the rinse liquid, a space between an opposing surface of a shielding plate and the main surface is filled with the rinse liquid, the opposing surfaces the main surface of the substrate, and in supplying the chemical liquid, the space between the opposing surface and the main surface is filled with the chemical liquid.

### Effects of the Invention

According to the first aspect, at the initial stage of the chemical liquid processing step, the chemical liquid is deposited on the rinse liquid covering the plurality of dies. Since the chemical liquid diffuses together with the rinse liquid, the chemical liquid is more likely to spread on the main surface of the substrate. Therefore, the chemical liquid starts to act more uniformly on the main surface of the substrate. Therefore, the chemical liquid processing can be more uniformly performed on the main surface of the substrate.

According to the second aspect, since the plurality of dies is present on the main surface of the substrate, the main surface of the substrate has an uneven shape. When the rotation speed of such a substrate increases, the rinse liquid splashes at the corner portion of each die. Moreover, when the rotation speed increases, the thickness of the liquid film of the rinse liquid on the main surface of the substrate decreases, and as a result, at least a part of the surfaces of the plurality of dies may be exposed without being covered with the rinse liquid. However, according to the second aspect, the substrate rotates at a rotation speed at which the rinse liquid covers the plurality of dies. Therefore, the rotation speed is relatively low, and liquid splashing of the rinse liquid can be suppressed.

Also in the second aspect, at the initial stage of the chemical liquid paddle step, the chemical liquid is deposited on the rinse liquid covering the plurality of dies. Since the chemical liquid diffuses together with the rinse liquid, the chemical liquid is more likely to spread on the main surface of the substrate. Therefore, the chemical liquid starts to act more uniformly on the main surface of the substrate. Therefore, the chemical liquid processing can be more uniformly performed on the main surface of the substrate.

According to the third aspect, the chemical liquid can be more uniformly supplied to the main surface of the substrate.

According to the fourth aspect, even after the rinse liquid on the main surface of the substrate is replaced with the chemical liquid, a new chemical liquid that has not yet reacted with the main surface of the substrate continues being dispensed from the first nozzle toward the main surface of the substrate. Therefore, the old chemical liquid that has reacted with the main surface of the substrate is pushed away by the new chemical liquid to flow down from the peripheral edge of the substrate, and the new chemical liquid acts on the main surface of the substrate. Therefore, the main surface of the substrate can be processed with a higher throughput.

According to the fifth aspect, the main surface of the substrate can be more uniformly processed.

According to the sixth aspect, since the same first nozzle as in the chemical liquid paddle step is used in the pre-paddle step, the processing is simple.

According to the seventh aspect, the rinse liquid is dispensed from the same first nozzle as in the chemical liquid paddle step. Therefore, at each position on the main surface of the substrate, it is possible to reduce the variation in the substantial processing time from the start of the supply of the chemical liquid to the supply of the rinse liquid. Therefore, the substrate can be more uniformly processed.

According to the eighth aspect, it is possible to further reduce the variation in the substantial processing time.

According to the ninth aspect, it is possible to scatter the chemical liquid remaining on the main surface of the substrate from the peripheral edge of the substrate to the outside also by the post-paddle process. That is, it is possible to more reliably replace the chemical liquid with the rinse liquid.

According to the tenth aspect, since the rinse liquid flows from the central portion of the substrate toward the peripheral edge portion of the substrate, the chemical liquid is more likely to be pushed to flow to the peripheral edge portion, and the chemical liquid can be more reliably replaced with the rinse liquid.

According to the eleventh aspect, since the substrate rotates at a rotation speed higher than the rotation speed in the replacement promotion step, the substrate can be dried more quickly. Conversely, since the rotation speed of the substrate W in the replacement promotion step is lower than the rotation speed of the substrate W in the drying step, liquid splashing of the rinse liquid can be suppressed in the replacement promotion step.

According to the twelfth aspect, since the rotation speed of the substrate is relatively high in the replacement promotion step, at least a part of the surfaces of the plurality of dies may be exposed without being covered with the rinse liquid. However, since the pre-paddle step is performed again after the replacement promotion step, the liquid film of the rinse liquid covers the plurality of dies at the time point of starting the chemical liquid paddle step. Therefore, in each chemical liquid paddle step, the chemical liquid can be started to act more uniformly on the main surface of the substrate.

According to the thirteenth aspect, the group of droplets of the processing liquid bounced back by the dies on the main surface of the substrate is directed downward. Therefore, it is possible to suppress scattering of the processing liquid around.

According to the fourteenth aspect, the chemical liquid can be more uniformly supplied to the main surface of the substrate.

According to the fifteenth aspect, the chemical liquid is supplied in a state in which the space between the shielding plate and the substrate is filled with the rinse liquid. Therefore, it is possible to avoid liquid splashing of the chemical liquid due to the dies on the main surface of the substrate.

### BRIEF DESCRIPTION OF DRAWINGS

FIG. 1 is a plan view schematically illustrating an example of a configuration of a substrate processing apparatus.

FIG. 2 is a plan view schematically illustrating an example of a configuration of a substrate.

FIG. 3 is a cross-sectional view schematically illustrating an example of a part of a configuration of a substrate.

FIG. 4 is a block diagram schematically illustrating an example of a configuration of a control unit.

FIG. 5 is a diagram schematically illustrating a first example of a configuration of a processing unit according to a first embodiment.

FIG. 6 is a flowchart illustrating a first example of substrate processing according to the first embodiment.

FIGS. 7A to 7C are diagrams schematically illustrating an example of a state of the processing unit in each step.

FIGS. 8A and 8B are diagrams schematically illustrating an example of the state of the processing unit in each step.

FIG. 9 is a graph illustrating an example of a temporal change in a rotation speed of the substrate.

FIG. 10 is a plan view schematically illustrating an example of a state in which a first nozzle reciprocates.

FIG. 11 is a diagram illustrating an example of a state in which a chemical liquid is deposited on a liquid film of a rinse liquid.

FIG. 12 is a plan view illustrating a positional relationship between the first nozzle and the substrate.

FIG. 13 is a graph illustrating a start timing, an end timing, and a substantial processing time at each position in the circumferential direction on the main surface of the substrate.

FIG. 14 is a diagram schematically illustrating a second example of the configuration of the processing unit according to the first embodiment.

FIG. 15 is a flowchart illustrating a second example of substrate processing according to the first embodiment.

FIG. 16 is a diagram schematically illustrating an example of a configuration of a processing unit according to a second embodiment.

FIG. 17 is a flowchart illustrating an example of substrate processing according to the second embodiment.

FIG. 18 is a diagram schematically illustrating an example of a configuration of a processing unit according to a third embodiment.

FIG. 19 is a cross-sectional view schematically illustrating an example of a part of the configuration of the substrate.

### DESCRIPTION OF EMBODIMENTS

Hereinafter, embodiments will be described in detail with reference to the drawings. In the drawings, dimensions and the number of units are exaggerated or simplified as necessary for easy understanding. Portions having similar configurations and functions are denoted by the same reference signs, and redundant description will be omitted in the following description.

Furthermore, in the following description, similar components are denoted by the same reference signs, and names and functions thereof are also similar. Therefore, detailed description thereof may be omitted in order to avoid duplication.

In addition, in the following description, even if ordinal numbers such as “first” or “second” are used, these terms are used for convenience to facilitate understanding of the contents of the embodiments, and are not intended to be limiting to any particular order that may be implied by these numbers.

When expressions indicating a relative or absolute positional relationship (for example, “in one direction”, “along one direction”, “parallel”, “orthogonal”, “center”, “concentric”, “coaxial”, etc.) are used, the expressions not only strictly represent the positional relationship, but also encompass states where angles or distances are relatively altered within a tolerance range or a range where equivalent functionality can be achieved, unless otherwise specified. When expressions indicating an equal state (for example, “same”, “equal”, “homogeneous”, etc.) are used, the expressions not only represent a quantitatively strictly equal state, but also represent a state where there is a tolerance or a difference which allows for obtaining a comparable function, unless otherwise specified. When expressions indicating a shape (for example, “quadrangular shape” or “cylindrical shape”, etc.) are used, the expressions not only represent the shape geometrically and strictly, but also represent a shape having, for example, irregularities or chamfering within a range in which a comparable effect can be obtained, unless otherwise specified. When the expression of “comprising”, “provided with”, “constituted of”, “including” or “having” one component is used, the expression is not an exclusive expression excluding the presence of other components. When the expression “at least any one of A, B, and C” is used, the expression includes only A, only B, only C, any two of A, B and C, and all of A, B and C.

### <Overall Configuration of Substrate Processing Apparatus>

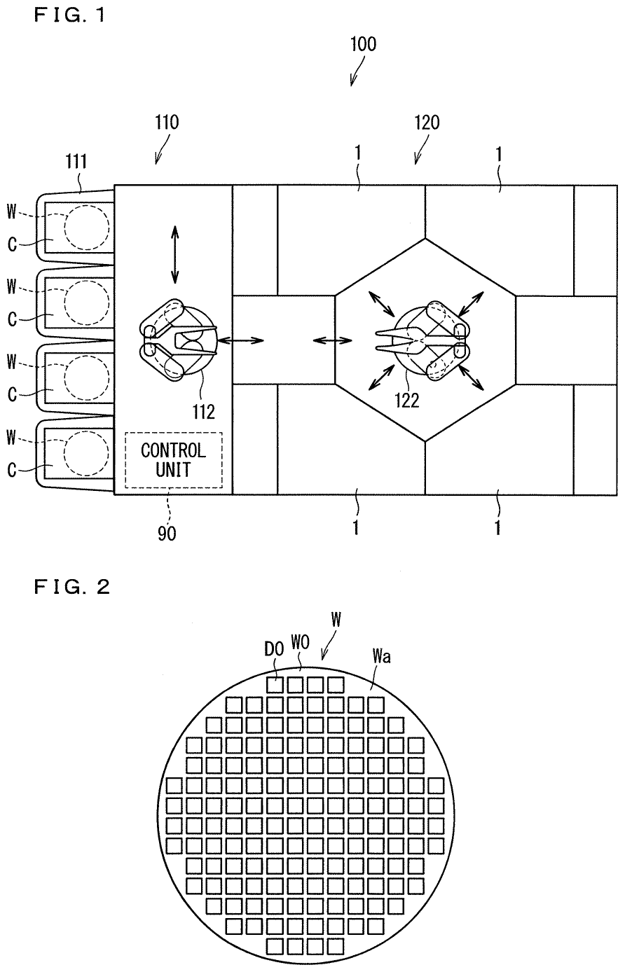

FIG. 1 is a plan view schematically illustrating an example of a configuration of a substrate processing apparatus 100. The substrate processing apparatus 100 is a single wafer type processing apparatus that processes substrates W one by one.

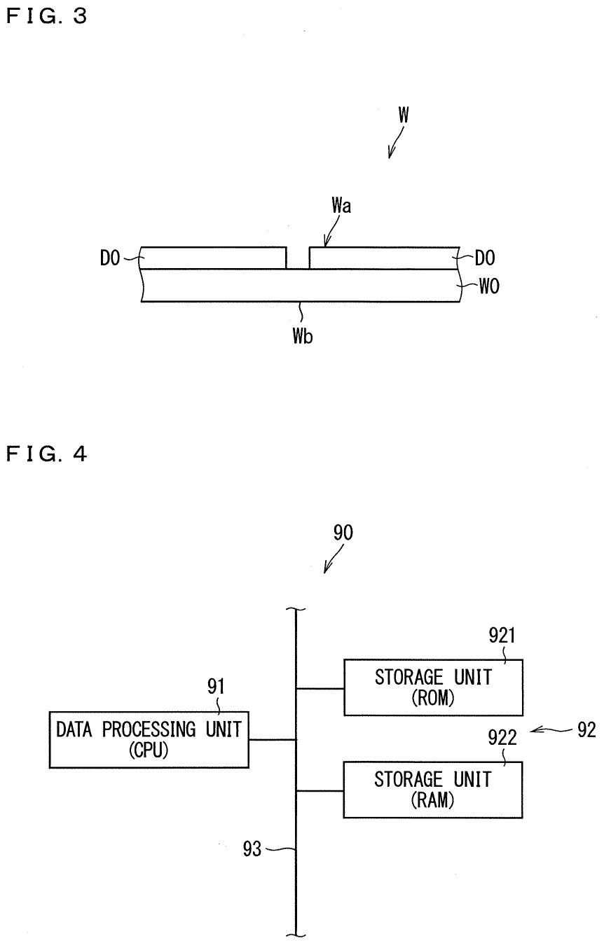

FIG. 2 is a plan view schematically illustrating an example of the configuration of the substrate W, and FIG. 3 is a cross-sectional view schematically illustrating an example of a part of the configuration of the substrate W. The substrate W has a plate shape. That is, the substrate W has a main surface Wa and a main surface Wb facing each other in the thickness direction. As illustrated in FIGS. 2 and 3, the substrate W has a plurality of dies D0 on its main surface Wa. The die D0 is a chip including an electronic circuit. The die D0 may also be referred to as semiconductor chip.

In the examples of FIGS. 2 and 3, the substrate W includes a support substrate W0 and the plurality of dies D0. The support substrate W0 has a plate shape. The support substrate W0 is not particularly limited, but is, for example, a semiconductor substrate or a glass substrate. In the example of FIG. 2, the support substrate W0 has a disk shape. The diameter of the support substrate W0 is, for example, about 300 mm. Both main surfaces of the support substrate W0 are flat, and the plurality of dies D0 is provided on one main surface of the support substrate W0.

The plurality of dies D0 are two-dimensionally arranged in plan view. Each die D0 has a plate shape, and is provided on the support substrate W0 in a state where one main surface thereof faces the main surface of the support substrate W0. For example, each die D0 may be bonded to the support substrate W0 with an adhesive or the like. In the example of FIG. 2, each die D0 has a rectangular shape in plan view. Specifically, the die D0 has a rectangular shape of, for example, about 10 mm×10 mm. In the example of FIG. 2, the plurality of dies D0 is arranged in a matrix in which a first direction along one side thereof is a row direction and a second direction intersecting the first direction is a column direction. The thickness of each die D0 may be, for example, 0.1 mm or more, 0.2 mm or more, 0.5 mm or more, or 1 mm or more. The minimum value of the interval (that is, the gap between the dies D0) between the dies D0 may be, for example, 0.1 μm or more, 1 μm or more, 10 μm or more, 100 μm or more, or 1 mm or more. The maximum value of the interval between the dies D0 may be 2 mm or less.

The main surface Wa of the substrate W includes a portion of one main surface of the support substrate W0 that is not covered with the plurality of dies D0 and a portion of the surfaces of the plurality of dies D0 that does not face the support substrate W0. Therefore, an uneven shape is formed on the main surface Wa of the substrate W by the dies D0. In the uneven shape, each die D0 corresponds to a protrusion. Since the thickness of each die D0 is larger than the thickness of the pattern included in the die D0, the depth of the irregularities formed on the main surface Wa of the substrate W is relatively large.

In the example of FIG. 1, the substrate processing apparatus 100 includes an indexer block 110, a processing block 120, and a control unit 90. The indexer block 110 is an interface unit for carrying in and out the substrate W between the processing block 120 and the outside. The processing block 120 mainly processes the substrate W received from the indexer block 110. The control unit 90 integrally controls the substrate processing apparatus 100.

### <Indexer Block 110>

In the example of FIG. 1, the indexer block 110 includes a plurality of load ports 111 and an indexer robot 112. Each load port 111 holds a board container (hereinafter referred to as carrier C) carried in from the outside. A plurality of substrates W is accommodated in the carrier C in a state of being aligned in the vertical direction. The indexer robot 112 is a conveyance unit that conveys the substrate W between the carrier C and the processing block 120. The indexer robot 112 sequentially takes out the unprocessed substrate W from the carrier C and conveys the substrate W to the processing block 120. In addition, the indexer robot 112 sequentially receives the processed substrates W which are processed by the processing block 120 from the processing block 120 and accommodates the substrates W in the carrier C. The carrier C accommodating the plurality of processed substrates W is carried out from the load port 111 to the outside.

### <Processing Block 120>

In the example of FIG. 1, the processing block 120 includes one or more processing units 1 and a center robot 122. In the example of FIG. 1, the processing block 120 includes a plurality of processing units 1. The center robot 122 is a conveyance unit that conveys the substrate W between the indexer robot 112 and the processing unit 1. The center robot 122 carries the unprocessed substrate W from the indexer robot 112 into the processing unit 1, and carries out the processed substrate W processed by the processing unit 1 from the processing unit 1. The center robot 122 transfers the substrate W to the indexer robot 112 after conveying the substrate W to another processing unit 1 as necessary.

Each processing unit 1 is a single wafer type apparatus that processes the substrates W one by one. An example of a specific configuration of the processing unit 1 will be described in detail later.

### <Control Unit 90>

The control unit 90 integrally controls the substrate processing apparatus 100. Specifically, the control unit 90 controls the indexer robot 112, the center robot 122, and the processing unit 1. FIG. 4 is a block diagram schematically illustrating an example of a configuration of the control unit 90. The control unit 90 is an electronic circuit, and includes, for example, a data processing unit 91 and a storage unit 92. In a specific example of FIG. 4, the data processing unit 91 and the storage unit 92 are connected to each other via a bus 93. The data processing unit 91 may be, for example, an arithmetic processing unit such as a central processor unit (CPU). The storage unit 92 may include a non-transitory storage unit (for example, a read only memory (ROM) or a hard disk) 921 and a temporary storage unit (for example, a random access memory (RAM)) 922. A non-transitory storage unit 921 may store, for example, a program that defines the processing to be executed by the control unit 90. When the data processing unit 91 executes this program, the control unit 90 can execute the processing defined in the program. Of course, part or all of the processing executed by the control unit 90 may be executed by hardware such as a dedicated logic circuit.

### <Processing Unit>

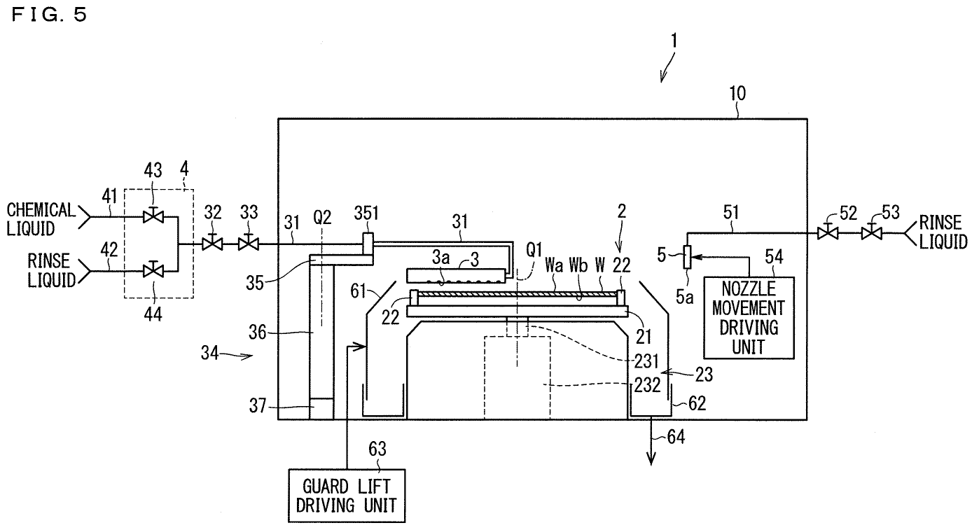

FIG. 5 is a diagram schematically illustrating a first example of a configuration of the processing unit 1 according to the first embodiment. Note that all the processing units 1 belonging to the substrate processing apparatus 100 do not need to have the configuration illustrated in FIG. 5. At least one processing unit 1 of the substrate processing apparatus 100 may have the configuration illustrated in FIG. 5.

The processing unit 1 supplies various processing liquids to the main surface Wa of the substrate W, and performs processing corresponding to the processing liquid on the substrate W (for example, the die D0). As illustrated in FIG. 5, the processing unit 1 includes a substrate holding unit 2 and a first nozzle 3.

In the example of FIG. 5, the processing unit 1 also includes a chamber 10. The chamber 10 has a box shape. The internal space of the chamber 10 corresponds to a processing space for processing the substrate W. The chamber 10 is provided with an openable and closable transfer port (not illustrated). The center robot 122 carries the unprocessed substrate W into the chamber 10 through the transfer port, and carries out the processed substrate W from the chamber 10 through the transfer port. The substrate W is carried into the chamber 10 in a posture in which the main surface Wa faces vertically upward.

The substrate holding unit 2 is provided in the chamber 10. The substrate holding unit 2 rotates the substrate W around a rotation axis Q1 while holding the substrate W in a horizontal posture. The horizontal posture here is a posture in which the thickness direction of the substrate W is the vertical direction. Since the substrate W is carried in in a state in which the main surface Wa faces vertically upward, the main surface Wa of the substrate W held by the substrate holding unit 2 corresponds to the upper surface. That is, the substrate holding unit 2 holds the substrate W in a posture in which the main surface Wa faces vertically upward. The rotation axis Q1 is an axis which passes through the center of the substrate W and is in the vertical direction. The substrate holding unit 2 may also be referred to as spin chuck.

In the example of FIG. 5, the substrate holding unit 2 includes a spin base 21, a chuck pin 22, and a rotation driving unit 23. The spin base 21 has a plate shape (for example, a disk shape), and is provided in a posture in which the thickness direction thereof is the vertical direction.

A plurality of chuck pins 22 is provided on the upper surface of the spin base 21. The plurality of chuck pins 22 is provided, for example, at equal intervals in the circumferential direction with respect to the rotation axis Q1. The plurality of chuck pins 22 is provided in a manner of being displaceable between holding positions and release positions to be described next. The holding position is a position where the chuck pin 22 abuts on the peripheral edge of the substrate W. When the plurality of chuck pins 22 stops at the respective holding positions, the plurality of chuck pins 22 holds the substrate W. FIG. 2 illustrates the chuck pin 22 stopped at the holding position. The release position is a position where each chuck pin 22 is separated from the substrate W. When the plurality of chuck pins 22 stops at the respective release positions, the holding of the substrate W by the chuck pins 22 is released. The substrate holding unit 2 also includes a pin driving unit (not illustrated) that displaces the chuck pins 22. The pin driving unit includes a driving source such as a motor or an air cylinder, and is controlled by the control unit 90.

The rotation driving unit 23 includes a shaft 231 and a motor 232. The upper end of the shaft 231 is connected to the lower surface of the spin base 21, and the shaft 231 extends from the lower surface of the spin base 21 along the rotation axis Q1. The motor 232 is controlled by the control unit 90 to rotate the shaft 231 around the rotation axis Q1. Thus, the spin base 21, the chuck pin 22, and the substrate W rotate integrally around the rotation axis Q1.

Note that the substrate holding unit 2 does not necessarily have the chuck pins 22. For example, the substrate holding unit 2 may hold the substrate W by a chuck method such as a vacuum chuck, an electrostatic chuck, or a Bernoulli chuck.

The first nozzle 3 is provided vertically above the substrate W held by the substrate holding unit 2 in the chamber 10. The first nozzle 3 dispenses the processing liquid toward the main surface Wa of the substrate W held by the substrate holding unit 2. In the example of FIG. 5, the first nozzle 3 can selectively dispense a chemical liquid and a rinse liquid as the processing liquid. In the example of FIG. 5, the first nozzle 3 is connected to the downstream end of a liquid supply pipe 31, the upstream end of the liquid supply pipe 31 is connected to a switching unit 4, and the switching unit 4 is also connected to the downstream end of a chemical liquid supply pipe 41 and the downstream end of a rinse liquid supply pipe 42. The upstream end of the chemical liquid supply pipe 41 is connected to a chemical liquid supply source (not illustrated), and the upstream end of the rinse liquid supply pipe 42 is connected to a rinse liquid supply source (not illustrated). The switching unit 4 is controlled by the control unit 90 to switch the pipe communicating with the liquid supply pipe 31 between the chemical liquid supply pipe 41 and the rinse liquid supply pipe 42.

The switching unit 4 may be, for example, a multi-valve. Specifically, the switching unit 4 may include a chemical liquid valve 43 and a rinse valve 44. These valves are controlled by the control unit 90. When the chemical liquid valve 43 is opened, the chemical liquid supply pipe 41 communicates with the liquid supply pipe 31. When a valve 32 described later is opened in this state, the chemical liquid from the chemical liquid supply source is supplied to the first nozzle 3 through the chemical liquid supply pipe 41, the switching unit 4, and the liquid supply pipe 31, and is dispensed from the first nozzle 3. When the rinse valve 44 is opened, the rinse liquid supply pipe 42 communicates with the liquid supply pipe 31. When the valve 32 described later is opened in this state, the rinse liquid from the rinse liquid supply source is supplied to the first nozzle 3 through the rinse liquid supply pipe 42, the switching unit 4, and the liquid supply pipe 31, and is dispensed from the first nozzle 3.

The chemical liquid is, for example, a mixed liquid of sulfuric acid and hydrogen peroxide water (SPM). In addition to the SPM, the chemical liquid may be a liquid containing at least one of sulfuric acid, acetic acid, nitric acid, hydrochloric acid, hydrofluoric acid, phosphoric acid, acetic acid, ammonia water, hydrogen peroxide water, an organic acid (for example, citric acid, oxalic acid), an organic alkali (for example, TMAH: tetramethylammonium hydroxide), a surfactant, and a corrosion inhibitor. The rinse liquid is, for example, pure water (that is, deionized water) or carbon dioxide water.

The chemical liquid supply pipe 41 may be provided with a heater (not illustrated). The heater heats the chemical liquid flowing through the chemical liquid supply pipe 41 to raise the temperature of the chemical liquid to a temperature suitable for processing. For example, when a mixed liquid of sulfuric acid and hydrogen peroxide water is applied as the chemical liquid, the temperature of the chemical liquid may be adjusted to, for example, a range which is higher than normal temperature and 80° C. or less. The heater is controlled by the control unit 90.

In the example of FIG. 5, the valve 32 and a flow rate adjusting valve 33 are interposed in the liquid supply pipe 31. When the valve 32 is opened, the processing liquid is dispensed from the first nozzle 3, and when the valve 32 is closed, the dispense of the processing liquid from the first nozzle 3 is stopped. The flow rate adjusting valve 33 adjusts the flow rate of the processing liquid flowing through the liquid supply pipe 31. The flow rate adjusting valve 33 may be a mass flow controller. The valve 32 and the flow rate adjusting valve 33 are controlled by the control unit 90.

In the example of FIG. 5, the first nozzle 3 is a shower nozzle. That is, the first nozzle 3 has a plurality of dispense ports 3a. In the example of FIG. 5, the first nozzle 3 extends in a direction (for example, a horizontal direction) along the main surface Wa of the substrate W, and the plurality of dispense ports 3a is formed on a lower surface of the first nozzle 3. The plurality of dispense ports 3a is arranged at intervals in the longitudinal direction of the first nozzle 3. The plurality of dispense ports 3a may be arranged in one row. The number of the dispense ports 3a is not particularly limited, and may be, for example, 10 or more or 15 or more. The dispense port 3a may have, for example, a circular shape in plan view, and its diameter may be set to, for example, about several mm.

In the example of FIG. 5, the processing unit 1 also includes a nozzle movement driving unit 34. The nozzle movement driving unit 34 is controlled by the control unit 90 to move the first nozzle 3 in the chamber 10. Specifically, the nozzle movement driving unit 34 moves the first nozzle 3 between a first processing position and a first standby position to be described next. The first processing position is a position where the first nozzle 3 dispenses the processing liquid onto the main surface Wa of the substrate W held by the substrate holding unit 2, and is a position facing the main surface Wa of the substrate W in the vertical direction. In the example of FIG. 5, the first nozzle 3 stopped at the first processing position is illustrated. The first standby position is a position where the first nozzle 3 does not dispense the processing liquid onto the main surface Wa of the substrate W held by the substrate holding unit 2, and is, for example, a position radially outward from the substrate W.

The first processing position may be a position where the longitudinal direction of the first nozzle 3 is the radial direction with respect to the rotation axis Q1. In other words, the first processing position may be a position where the plurality of dispense ports 3a of the first nozzle 3 is arranged in the radial direction. At the first processing position, the dispense port 3a closest to the rotation axis Q1 among the plurality of dispense ports 3a of the first nozzle 3 faces the central portion of the main surface Wa of the substrate W in the vertical direction, and the dispense port 3a farthest from the rotation axis Q1 among the plurality of dispense ports 3a faces the peripheral portion of the main surface Wa of the substrate W in the vertical direction. The interval between the dispense port 3a closest to the rotation axis Q1 and the dispense port 3a farthest from the rotation axis Q1 (for example, the interval between the centers of the dispense ports 3a) may be ½ or more, ⅔ or more, ¾ or more, or ⅘ or more of the radius of the substrate W.

In the example of FIG. 5, the nozzle movement driving unit 34 includes an arm 35, a support column 36, and a rotation driving unit 37. The support column 36 has a columnar shape extending in the vertical direction, and is provided radially outward from the substrate holding unit 2 in plan view. The arm 35 has a rod-like shape extending in the horizontal direction, and a base end portion thereof is connected to the support column 36. A pipe holding portion 351 which is penetrated by the liquid supply pipe 31 is provided at a distal end portion of the arm 35. The pipe holder 351 holds the liquid supply pipe 31. The rotation driving unit 37 includes a motor (not illustrated) controlled by the control unit 90, and rotates the support column 36 in forward and reverse directions within a predetermined angle range around a central axis line Q2 of the support column 36. Thus, the first nozzle 3 reciprocates in the circumferential direction with respect to the central axis line Q2. Note that the nozzle movement driving unit 34 does not necessarily have the above-described configuration, and may include, for example, a linear motion driving unit such as a ball screw mechanism or a linear motor.

In the example of FIG. 5, the processing unit 1 also includes a second nozzle 5. The second nozzle 5 is provided vertically above the substrate W held by the substrate holding unit 2 in the chamber 10. The second nozzle 5 dispenses the rinse liquid toward the main surface Wa of the substrate W held by the substrate holding unit 2. The second nozzle 5 has, for example, a shape extending in the vertical direction, and has the dispense port 5a on a lower surface thereof. In the example of FIG. 5, the second nozzle 5 has a single dispense port 5a.

The second nozzle 5 is connected to the downstream end of the rinse liquid pipe 51, and the upstream end of the rinse liquid pipe 51 is connected to the rinse liquid supply source (not illustrated). A valve 52 and a flow rate adjusting valve 53 are interposed in the rinse liquid pipe 51. When the valve 52 is opened, the rinse liquid is dispensed from the second nozzle 5, and when the valve 52 is closed, the dispense of the rinse liquid from the second nozzle 5 is stopped. The flow rate adjusting valve 53 adjusts the flow rate of the rinse liquid flowing through the rinse liquid pipe 51. The flow rate adjusting valve 53 may be a mass flow controller. The valve 52 and the flow rate adjusting valve 53 are controlled by the control unit 90.

In the example of FIG. 5, the processing unit 1 also includes a nozzle movement driving unit 54. The nozzle movement driving unit 54 is controlled by the control unit 90 to move the second nozzle 5 between a second processing position and a second standby position to be described next. The second processing position is a position where the second nozzle 5 dispenses the processing liquid onto the main surface Wa of the substrate W held by the substrate holding unit 2, and is, for example, a position facing the central portion of the main surface Wa of the substrate W in the vertical direction. The second standby position is a position where the second nozzle 5 does not dispense the processing liquid onto the main surface Wa of the substrate W held by the substrate holding unit 2, and is, for example, a position radially outward from the substrate W. FIG. 5 illustrates the second nozzle 5 stopped at the second standby position. An example of a specific configuration of the nozzle movement driving unit 54 is similar to the configuration of the nozzle movement driving unit 34.

When the processing liquid is dispensed from the first nozzle 3 or the second nozzle 5 toward the main surface Wa of the rotating substrate W, the processing liquid is supplied to the entire surface of the main surface Wa of the substrate W. Thus, a processing corresponding to the processing liquid is performed on the substrate W.

In the example of FIG. 5, the processing unit 1 also includes a guard 61 and a guard lift driving unit 63. The guard 61 has a tubular shape surrounding the substrate W held by the substrate holding unit 2. The guard lift driving unit 63 is controlled by the control unit 90 to lift and lower the guard 61 between an upper position and a lower position described next. The upper position is a position where the upper end of the guard 61 is vertically above the main surface Wa of the substrate W held by the substrate holding unit 2. In FIG. 5, the guard 61 stopped at the upper position is illustrated. In a state where the guard 61 is located at the upper position, when the processing liquid scatters radially outward from the peripheral edge of the substrate W, the guard 61 can receive the scattered processing liquid. The lower position is a position where the upper end of the guard 61 is vertically lower than the upper position, and is, for example, a position vertically lower than the upper surface of the spin base 21. The guard lift driving unit 63 includes, for example, a ball screw mechanism or an air cylinder.

A cup 62 receives the processing liquid flowing down on the inner peripheral surface of the guard 61. The upstream end of a collection pipe 64 is connected to a lower portion of the cup 62, and the processing liquid received by the cup 62 is collected through the collection pipe 64. The cup 62 may be separate from the guard 61 or may be formed integrally with the guard 61.

### <First Example of Substrate Processing>

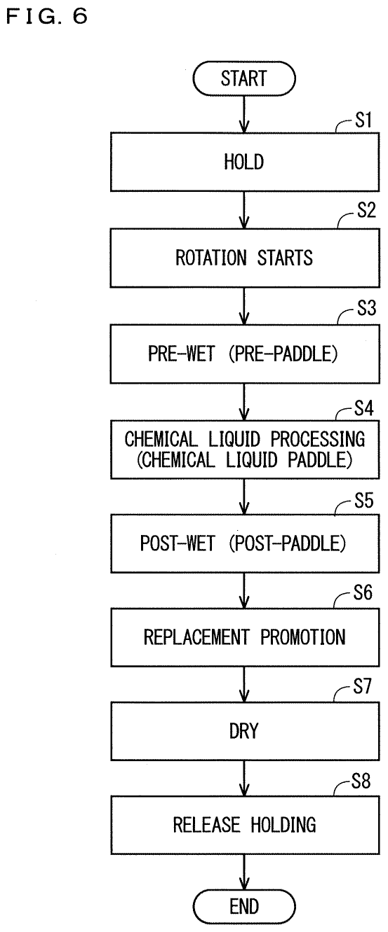

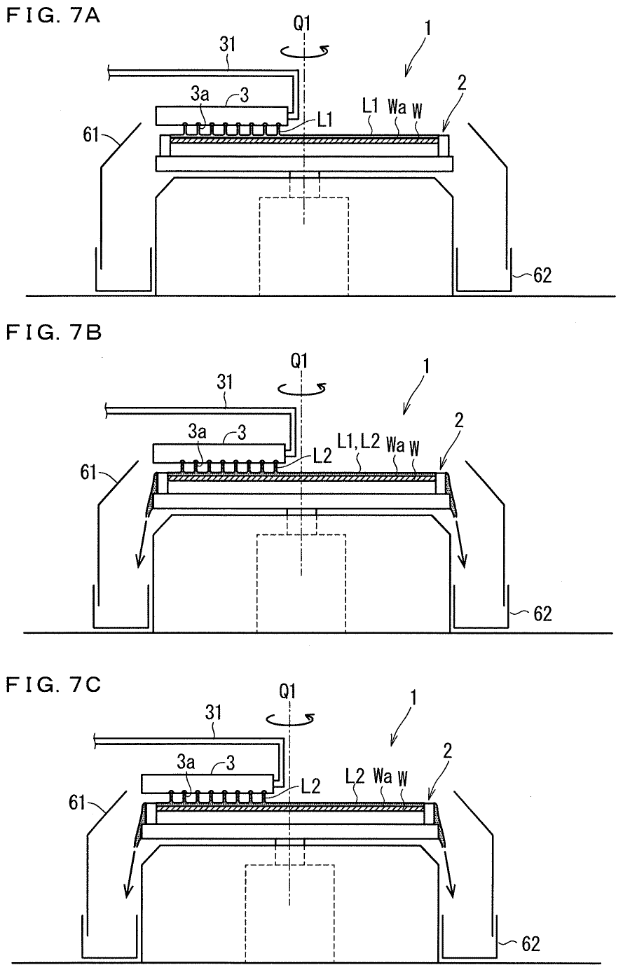

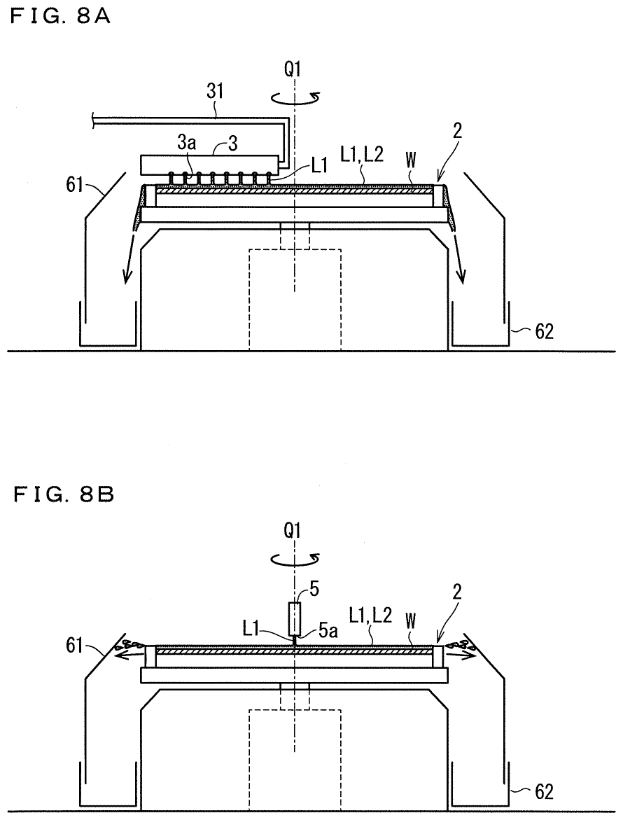

FIG. 6 is a flowchart illustrating a first example of substrate processing according to the first embodiment. FIGS. 7A to 7C, 8A and 8B are diagrams schematically illustrating an example of a state of the processing unit 1 in each step.

First, the center robot 122 carries the substrate W into the chamber 10 of the processing unit 1, and the substrate holding unit 2 receives the substrate W and holds the substrate W (step S1: holding step). As a specific example, the substrate holding unit 2 displaces the plurality of chuck pins 22 from the respective release positions to the holding positions. Thus, the plurality of chuck pins 22 holds the substrate W. The substrate holding unit 2 continues to hold the substrate W until the processing on the substrate W is completed. Further, here, at the time of being carried into the chamber 10, the main surface Wa of the substrate W is generally in a dry state.

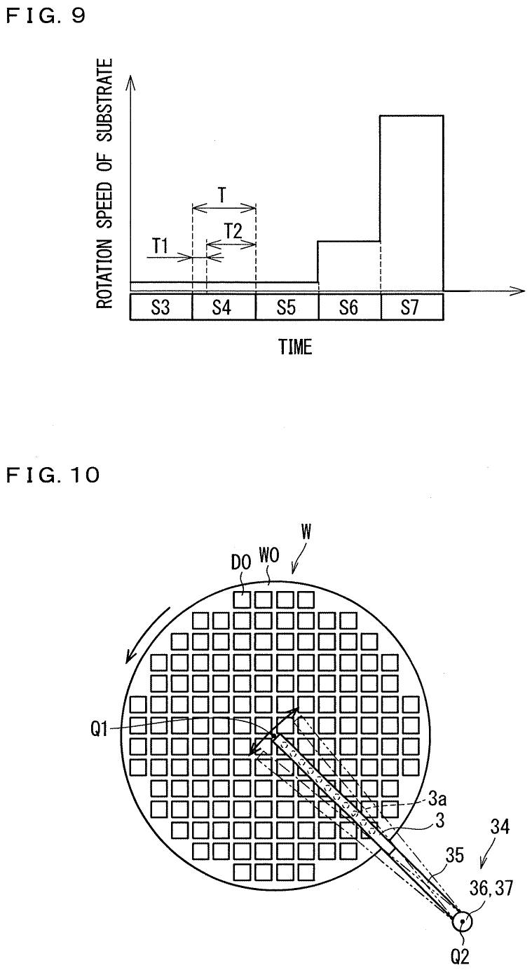

Next, the substrate holding unit 2 starts rotating the substrate W around the rotation axis Q1 (step S2). The substrate holding unit 2 may maintain the rotation of the substrate W until the processing on the substrate W is completed. FIG. 9 is a graph illustrating an example of a temporal change in a rotation speed (for example, a target value) of the substrate W. The rotation speed of the substrate W in each step will be described later. After step S1, the guard lift driving unit 63 may raise the guard 61 to the upper position.

Next, the processing unit 1 supplies a rinse liquid L1 to the main surface Wa of the substrate W (step S3: pre-wet step). FIG. 7A illustrates an example of a state of the processing unit 1 in step S3. In step S3, the substrate holding unit 2 rotates the substrate W at a rotation speed at which the surfaces of the dies D0 of the substrate W are covered with the rinse liquid L1. As a specific example, the substrate holding unit 2 rotates the substrate W at a rotation speed of 20 rpm or less. The rotation speed of the substrate W may be 15 rpm or less. Note that the target value of the rotation speed of the substrate W may be set constant over step S3 (see also FIG. 9). The control unit 90 controls the substrate holding unit 2 (specifically, the motor 232) based on the target value such that the rotation speed of the substrate W approaches the target value.

The processing unit 1 supplies the rinse liquid L1 to the main surface Wa of the substrate W while rotating the substrate W at the rotation speed. The processing unit 1 supplies the rinse liquid L1 to the main surface Wa of the substrate W using the first nozzle 3 or the second nozzle 5 to form a liquid film of the rinse liquid L1 covering the plurality of dies D0. Here, as an example, the first nozzle 3 is used. Specifically, first, the nozzle movement driving unit 34 moves the first nozzle 3 to the first processing position. Then, the control unit 90 opens the rinse valve 44 and the valve 32. Thus, the rinse liquid L1 is dispensed from the plurality of dispense ports 3a of the first nozzle 3 in a continuous flow state (see also FIG. 7A). The flow rate adjusting valve 33 adjusts the flow rate of the rinse liquid L1 to be, for example, 0.1 L (liter)/min or more and 2.0 L/min or less. The flow rate of the rinse liquid L1 may be adjusted to 1.0 L/min or more.

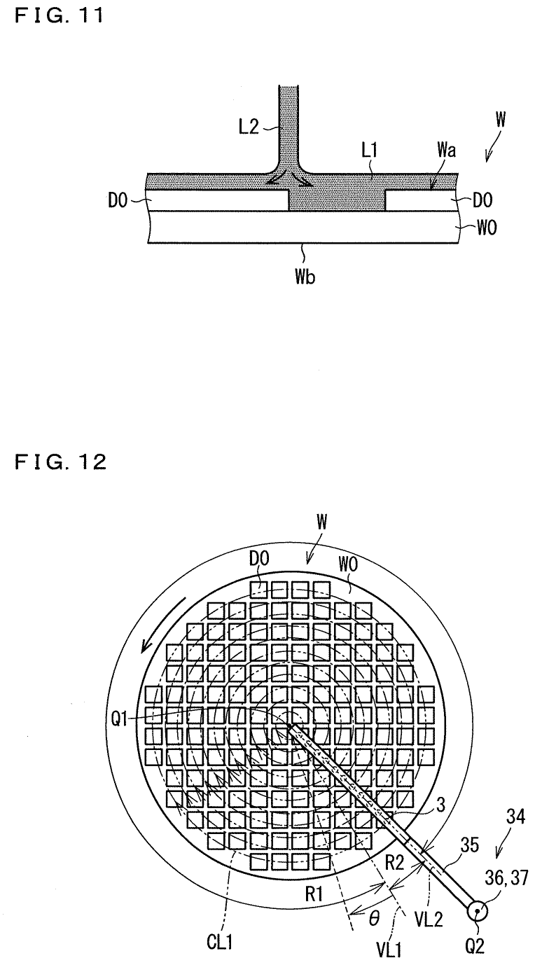

As described above, in step S3, the first nozzle 3 dispenses the rinse liquid L1 toward the main surface Wa of the substrate W rotating at a low speed. If the rotation speed of the substrate W increases, the liquid film of the rinse liquid L1 on the main surface Wa of the substrate W becomes thin, and thus, at least a part of the surfaces of the dies D0 may be exposed without being covered with the rinse liquid L1. On the other hand, in step S3, the substrate holding unit 2 rotates the substrate W at a rotation speed of, for example, 20 rpm or less (or 15 rpm or less). Therefore, the thickness of the liquid film of the rinse liquid L1 is large, and the rinse liquid L1 can cover the surfaces of the plurality of dies D0. Here, the thickness of a portion between the dies D0 of the liquid film of the rinse liquid L1 may be greater than or equal to the thickness of the die D0 (see also FIG. 11 described later). In addition, in this example, the liquid film is maintained on the main surface Wa of the substrate W at a low rotation speed, and thus, it can be said that step S3 is a so-called paddle processing. Therefore, hereinafter, the pre-wet step is also referred to as pre-paddle step.

In step S3 (pre-paddle step), the nozzle movement driving unit 34 may reciprocate the first nozzle 3 within a predetermined movement range in a direction along the main surface Wa of the substrate W (for example, the horizontal direction). Such reciprocating movement may also be referred to as swinging. FIG. 10 is a plan view schematically illustrating an example of a state in which the first nozzle 3 reciprocates. The predetermined movement range is, for example, a range in which the longitudinal direction of the first nozzle 3 includes a reference position in the radial direction with respect to the rotation axis Q1 as the center. In FIG. 10, the first nozzle 3 located at the reference position is indicated by solid lines. For example, the nozzle movement driving unit 34 may move the first nozzle 3 such that the dispense port 3a closest to the rotation axis Q1 reciprocates within a movement range of about ±several tens mm (for example, 40 mm) about the reference position.

When the nozzle movement driving unit 34 reciprocates the first nozzle 3 in this manner, the liquid landing position of the rinse liquid L1 from each dispense port 3a can be moved. Specifically, each liquid landing position moves not only in the circumferential direction with respect to the rotation axis Q1 but also in the radial direction. Therefore, the processing unit 1 can more uniformly supply the rinse liquid L1 to the main surface Wa of the substrate W. Therefore, the processing unit 1 can more quickly form a liquid film of the rinse liquid L1 having excellent coverage.

When the liquid film of the rinse liquid L1 is formed to an extent sufficient to cover the surfaces of the plurality of dies D0, the processing unit 1 stops the supply of the rinse liquid L1. As a specific example, when a predetermined pre-time has elapsed since the start of the supply of the rinse liquid L1, the control unit 90 executes step S4 described later. Note that the pre-time is set in advance and stored in, for example, the storage unit 921. The same applies to other times described later. The elapsed time is measured by, for example, an unillustrated timer circuit included in the control unit 90.

Next, the processing unit 1 dispenses a chemical liquid L2 from the first nozzle 3 toward the main surface Wa of the substrate W while rotating the substrate W at a rotation speed at which the surfaces of the plurality of dies D0 are covered with the chemical liquid L2 (step S4: chemical liquid processing step). FIGS. 7B and 7C illustrate an example of a state of the processing unit 1 in step S4. FIG. 7B illustrates an example of a state of the processing unit 1 at the initial stage of step S4, and FIG. 7C illustrates an example of a state of the processing unit 1 thereafter.

For example, the substrate holding unit 2 rotates the substrate W at a rotation speed of 20 rpm or less. The rotation speed of the substrate W may be set to 15 rpm or less. In addition, the target value of the rotation speed of the substrate W may be set constant over step S4 (see also FIG. 9). In the example of FIG. 9, the rotation speed of the substrate W in step S4 is the same as the rotation speed of the substrate W in step S3. Here, these rotation speeds may be different from each other.

The processing unit 1 supplies the chemical liquid L2 to the main surface Wa of the substrate W rotating at a low speed using the first nozzle 3. Specifically, the control unit 90 closes the rinse valve 44 and opens the chemical liquid valve 43 and the valve 32. Thus, the chemical liquid L2 is dispensed from the plurality of dispense ports 3a of the first nozzle 3 toward the main surface Wa of the substrate W in a continuous flow state (see FIG. 7B). The flow rate adjusting valve 33 adjusts the flow rate of the chemical liquid L2 to be, for example, 0.1 L/min or more and 2.0 L/min or less. The flow rate of the chemical liquid L2 may be set to 1.0 L/min or more.

As described above, in step S4, the first nozzle 3 dispenses the chemical liquid L2 toward the main surface Wa of the substrate W rotating at a low speed. At the initial stage of step S4, the chemical liquid L2 is deposited on the liquid film of the rinse liquid L1 on the main surface Wa of the substrate W. FIG. 11 is a view illustrating an example of a state in which the chemical liquid L2 is deposited on the liquid film of the rinse liquid L1. As illustrated in FIG. 11, since the chemical liquid L2 is deposited on the liquid film of the rinse liquid L1, the chemical liquid L2 is not directly deposited on the corner portion of the die D0. Therefore, it is possible to suppress liquid splashing of the chemical liquid L2. Moreover, since the chemical liquid L2 can flow together with the rinse liquid L1 on the main surface Wa of the substrate W, the chemical liquid L2 is more likely to flow along the main surface Wa of the substrate W. Therefore, even at the initial stage of step S4, the chemical liquid L2 can spread more uniformly from each liquid landing position.

Due to the supply of the chemical liquid L2, the processing liquid (the rinse liquid L1 and the chemical liquid L2) on the main surface Wa overflows from the peripheral edge of the substrate W. In step S4, since the rotation speed of the substrate W is low, the processing liquid flows down from the peripheral edge of the substrate W without being scattered to the inner peripheral surface of the guard 61 (see FIGS. 7B and 7C). In other words, the substrate holding unit 2 rotates the substrate W at a rotation speed at which the processing liquid from the peripheral edge of the substrate W flows down without reaching the guard 61. The processing liquid which has flown down from the peripheral edge of the substrate W is received by the cup 62 and collected through the collection pipe 64.

Since the processing liquid overflows from the main surface Wa of the substrate W due to the supply of the chemical liquid L2, the processing liquid on the main surface Wa is replaced from the rinse liquid L1 with the chemical liquid L2. As described above, since the chemical liquid L2 can spread on the main surface Wa more uniformly from the initial stage of step S4, the rinse liquid L1 can be replaced with the chemical liquid L2 more uniformly. Therefore, the chemical liquid L2 starts to more uniformly act on the main surface Wa of the substrate W. In other words, it is possible to reduce the variation in the distribution on the main surface Wa at the start timing at which the chemical liquid L2 starts to act on each position on the main surface Wa of the substrate W.

As described above, when the first nozzle 3 dispenses the chemical liquid L2 from the plurality of dispense ports 3a arranged in the radial direction, it is possible to effectively reduce the variation in start timing particularly in the radial direction.

Also in step S4, since the rotation speed of the substrate W is low, the liquid film of the chemical liquid L2 on the main surface Wa of the substrate W can be thickened, and the liquid film of the chemical liquid L2 can cover the surfaces of the plurality of dies D0 of the substrate W. Therefore, the chemical liquid L2 can more appropriately act on the main surface Wa (particularly, the die D0) of the substrate W. That is, the main surface Wa of the substrate W can be appropriately subjected to the chemical liquid processing. Here, the thickness of a portion between the dies D0 of the liquid film of the chemical liquid L2 can be greater than or equal to the thickness of the die D0. In this example, since the liquid film is maintained on the main surface Wa of the substrate W at a low rotation speed, it can be said that step S4 is also a so-called paddle processing. Therefore, hereinafter, the chemical liquid processing step is also referred to as chemical liquid paddle step.

By the way, since the chemical liquid L2 on the main surface Wa of the substrate W reacts with the main surface Wa of the substrate W, the active component in the chemical liquid L2 is reduced by the reaction. Reduction of the active component leads to insufficiency of processing or a decrease in throughput. In addition, foreign substances such as by-products are also generated by the reaction. It is not desirable that the foreign substances remain on the main surface Wa of the substrate W.

Therefore, the processing unit 1 may continue to dispense the chemical liquid L2 from the first nozzle 3 toward the main surface Wa of the substrate W even after replacing the rinse liquid L1 with the chemical liquid L2. Since the new chemical liquid L2 continues to be supplied from the first nozzle 3 to the main surface Wa of the substrate W, the chemical liquid L2 containing the sufficient active component reacts with the main surface Wa of the substrate W. Therefore, it is possible to suppress insufficiency of processing on the main surface Wa of the substrate W. Alternatively, the throughput of the processing can be improved. The foreign substances generated by the reaction flow down from the peripheral edge of the substrate W together with the old chemical liquid L2. Therefore, the possibility that the foreign substances remain on the main surface Wa of the substrate W can be reduced.

Here, when a substantial time required for replacement of the rinse liquid L1 with the chemical liquid L2 on the main surface Wa of the substrate W is defined as a replacement time T1, an actual processing time T2 for continuously dispensing the chemical liquid L2 after the elapse of the replacement time T1 may be set longer than the replacement time T1 (see FIG. 9). For example, the actual processing time T2 may be 1.5 times or more, 2 times or more, 5 times or more, or 10 times or more the replacement time T1. According to this, the processing using the chemical liquid can be sufficiently performed on the main surface Wa (for example, the die D0) of the substrate W.

The nozzle movement driving unit 34 may reciprocate the first nozzle 3 in the horizontal direction within a predetermined movement range in step S4 (chemical liquid paddle step) (see FIG. 10). The movement range may be, for example, the same as the movement range in step S3. When the nozzle movement driving unit 34 reciprocates the first nozzle 3, the liquid landing position of the chemical liquid L2 from each dispense port 3a can be moved. Thus, the chemical liquid L2 can more uniformly act on the main surface Wa of the substrate W. In particular, depending on the type of the chemical liquid L2, the processing at the liquid landing position may be promoted more than the processing at a position other than the liquid landing position. When the chemical liquid L2 is used, non-uniformity of the chemical liquid processing can be effectively suppressed by the reciprocating movement of the first nozzle 3.

When the processing with the chemical liquid L2 is sufficiently performed, the processing unit 1 stops the supply of the chemical liquid L2. As a specific example, when a predetermined chemical liquid processing time T (that is, the sum of the replacement time T1 and the actual processing time T2) has elapsed since the start of the supply of the chemical liquid L2, the control unit 90 executes step S5 described later.

Next, the processing unit 1 dispenses the rinse liquid L1 from the first nozzle 3 toward the main surface Wa of the substrate W while rotating the substrate W at a rotation speed at which the surfaces of the plurality of dies D0 are covered with the rinse liquid L1 (step S5: post-wet step). FIG. 8A illustrates an example of a state of the processing unit 1 in step S5.

For example, the substrate holding unit 2 rotates the substrate W at a rotation speed of 20 rpm or less. The rotation speed of the substrate W may be set to 15 rpm or less. In addition, the target value of the rotation speed of the substrate W may be set constant over step S5 (see also FIG. 9). As illustrated in FIG. 9, the rotation speed (for example, the target value) of the substrate W in step S5 may be the same as the rotation speed (for example, the target value) of the substrate W in step S4.

The processing unit 1 supplies the rinse liquid L1 to the main surface Wa of the substrate W rotating at a low speed using the first nozzle 3. Specifically, the control unit 90 closes the chemical liquid valve 43 and opens the rinse valve 44 and the valve 32. Thus, the rinse liquid L1 is dispensed from the plurality of dispense ports 3a of the first nozzle 3 in a continuous flow state (see FIG. 8A). The flow rate adjusting valve 33 adjusts the flow rate of the rinse liquid L1 to be, for example, 0.1 L/min or more and 2.0 L/min or less. The flow rate of the rinse liquid L1 may be set to 1.0 L/min or more.

Since the liquid film of the chemical liquid L2 is formed on the main surface Wa of the substrate W in step S4 immediately before step S5, the rinse liquid L1 is deposited on the liquid film of the chemical liquid L2 on the main surface Wa of the substrate W at the initial stage of step S5. Therefore, splashing of the rinse liquid L1 can be suppressed. In addition, since the rinse liquid L1 can flow together with the chemical liquid L2 on the main surface Wa of the substrate W, the rinse liquid L1 can more uniformly spread from each liquid landing position.

Due to the supply of the rinse liquid L1, the processing liquid (the rinse liquid L1 and the chemical liquid L2) on the main surface Wa overflows from the peripheral edge of the substrate W. In step S5, since the rotation speed of the substrate W is low, the processing liquid flows down without being scattered to the inner peripheral surface of the guard 61. In other words, the substrate holding unit 2 rotates the substrate W at a rotation speed at which the processing liquid from the peripheral edge of the substrate W flows down without reaching the guard 61. The processing liquid which has flown down from the peripheral edge of the substrate W is received by the cup 62 and collected through the collection pipe 64.

Since the processing liquid overflows from the main surface Wa of the substrate W due to the supply of the rinse liquid L1, the processing liquid on the main surface Wa is replaced from the chemical liquid L2 with the rinse liquid L1. As described above, since the rinse liquid L1 can spread on the main surface Wa more uniformly from the initial stage of step S5, the chemical liquid L2 can be replaced with the rinse liquid L1 more uniformly. By this replacement, the action of the chemical liquid L2 to each position on the main surface Wa of the substrate W is substantially terminated. Therefore, it is possible to reduce the variation in the distribution on the main surface Wa at the stop timing at which the chemical liquid L2 finishes acting on each position on the main surface Wa of the substrate W.

Also in step S5, since the rotation speed of the substrate W is low, the liquid film of the rinse liquid L1 on the main surface Wa of the substrate W can be thickened, and the liquid film of the rinse liquid L1 can cover the surfaces of the plurality of dies D0 of the substrate W. Here, the thickness of the portion between the dies D0 of the liquid film of the rinse liquid L1 can be greater than or equal to the thickness of the die D0. In this example, since the liquid film is maintained on the main surface Wa of the substrate W at a low rotation speed, it can be said that step S5 is also a so-called paddle processing. Therefore, hereinafter, the post-wet step is also referred to as post-paddle step.

The nozzle movement driving unit 34 may reciprocate the first nozzle 3 in the horizontal direction within a predetermined movement range also in step S5 (post-paddle step) (see FIG. 10). The movement range may be, for example, the same as the movement range in step S4. When the nozzle movement driving unit 34 reciprocates the first nozzle 3 in this manner, the liquid landing position of the rinse liquid L1 from each dispense port 3a can be moved. Thus, the rinse liquid L1 can be more uniformly supplied to the main surface Wa of the substrate W. Therefore, the processing unit 1 can more uniformly replace the chemical liquid L2 with the rinse liquid L1.

As described above, in step S5, the processing liquid on the main surface Wa is generally replaced from the chemical liquid L2 with the rinse liquid L1. Here, since the rotation speed of the substrate W is low, the chemical liquid L2 may slightly remain on the main surface Wa of the substrate W.

When the replacement of the chemical liquid L2 with the rinse liquid L1 proceeds to some extent, the processing unit 1 executes step S6 described later. For example, when a predetermined post time has elapsed since the supply of the rinse liquid L1, the processing unit 1 supplies the rinse liquid L1 to the main surface Wa of the substrate W while increasing the rotation speed of the substrate W (step S6: substitution promotion step, see also FIG. 9).

Here, as an example, the processing unit 1 switches the nozzle for dispensing the rinse liquid L1 from the first nozzle 3 to the second nozzle 5. That is, the processing unit 1 supplies the rinse liquid L1 to the main surface Wa of the substrate W using the second nozzle 5. FIG. 8B is a diagram schematically illustrating an example of a state of the processing unit 1 in step S6.

Specifically, the control unit 90 closes the valve 32, causes the nozzle movement driving unit 34 to move the first nozzle 3 to the first standby position, causes the nozzle movement driving unit 54 to move the second nozzle 5 to the second processing position, opens the valve 52, and causes the substrate holding unit 2 to increase the rotation speed of the substrate W. Thus, the rinse liquid L1 is dispensed in a continuous flow state from the single dispense port 5a of the second nozzle 5 toward the central portion of the main surface Wa of the substrate W rotating at a relatively high rotation speed. The central portion here may be, for example, a portion in a circular region having a diameter of ⅕ or less of the diameter of the substrate W. The rotation speed of the substrate W may be set to, for example, about 100 rpm or more and 1200 rpm or less, 100 rpm or more and 500 rpm or less, or 200 rpm or more and 500 rpm or less.

The rinse liquid L1 that has been deposited on the central portion of the main surface Wa of the substrate W flows radially outward through the main surface Wa and scatters from the peripheral edge of the substrate W (see FIG. 8B). The rinse liquid L1 scattered from the peripheral edge of the substrate W may be received by the inner peripheral surface of the guard 61. In other words, the substrate holding unit 2 may be rotated at a rotation speed at which the rinse liquid L1 reaches the inner peripheral surface of the guard 61.

As described above, in step S6, the rotation speed of the substrate W is relatively high. Therefore, the centrifugal force generated in the processing liquid on the main surface Wa of the substrate W is relatively large, and the processing liquid is more likely to flow radially outward. Therefore, the chemical liquid L2 remaining on the main surface Wa of the substrate W is also more likely to flow radially outward and scatter (or flow down) outward from the peripheral edge of the substrate W. Therefore, the replacement efficiency from the chemical liquid L2 to the rinse liquid L1 can be improved.

Moreover, in the above-described example, in step S6, the second nozzle 5 dispenses the rinse liquid L1 toward the central portion of the main surface Wa of the substrate W. Therefore, the rinse liquid L1 flows radially outward through the main surface Wa of the substrate W from the central portion of the main surface Wa of the substrate W. Therefore, the rinse liquid L1 can push the processing liquid on the main surface Wa of the substrate W to flow radially outward. That is, the chemical liquid L2 remaining on the main surface Wa is pushed to flow radially outward by the rinse liquid L1, and scatters (or flows down) outward from the peripheral edge of the substrate W together with the rinse liquid L1. Thus, the replacement efficiency from the chemical liquid L2 to the rinse liquid L1 can be further improved.

When the replacement of the chemical liquid L2 with the rinse liquid L1 is sufficiently performed, the processing unit 1 stops the supply of the rinse liquid L1. For example, when a predetermined replacement promotion time has elapsed since the start of the increase in the rotation speed of the substrate W, the control unit 90 closes the valve 52. Thus, the supply of the rinse liquid L1 from the second nozzle 5 is stopped.

Next, the processing unit 1 dries the substrate W (step S7: drying step). As a specific example, the substrate holding unit 2 further increases the rotation speed of the substrate W (so-called spin drying, see also FIG. 9). The rotation speed of the substrate W may be set to, for example, more than 1200 rpm, 1500 rpm or more, or 2000 rpm or more. Since the rotation speed of the substrate W is higher than the rotation speed of the substrate W in step S6, the amount of the processing liquid scattered from the peripheral edge of the substrate W can be increased. In addition, the evaporation of the processing liquid of the substrate W can be promoted by the airflow. Therefore, the substrate W can be dried more quickly.

Conversely, since the rotation speed of the substrate W in step S6 is lower than the rotation speed of the substrate W in step S7, liquid splashing of the rinse liquid L1 can be suppressed in step S6.

When the substrate W is sufficiently dried, the processing unit 1 stops the rotation of the substrate W. For example, when a predetermined drying time has elapsed since the increase in the rotation speed, the substrate holding unit 2 stops the rotation of the substrate W.

Next, the substrate holding unit 2 releases the holding of the substrate W (step S8: holding releasing step). Specifically, the substrate holding unit 2 displaces the plurality of chuck pins 22 from the respective holding positions to the release positions. Thus, the holding of the substrate W is released. Next, the center robot 122 carries out the substrate W from the processing unit 1.

As described above, the processing unit 1 can perform various types of processing on the substrate W whose main surface Wa has an uneven shape by the plurality of dies D0.

According to the present substrate processing method, in step S3 (pre-paddle step), the processing unit 1 supplies the rinse liquid L1 to the main surface Wa of the substrate W while rotating the substrate W at a rotation speed at which the surfaces of the plurality of dies D0 are covered with the rinse liquid L1. In step S3, just because the rotation speed of the substrate W is low, the liquid film of the rinse liquid L1 can be increased to such an extent that the rinse liquid L1 covers the surfaces of the plurality of dies D0.

In the next step S4 (chemical liquid paddle step), the processing unit 1 dispenses the chemical liquid L2 from the first nozzle 3 toward the main surface Wa of the substrate W while rotating the substrate W at a rotation speed at which the surfaces of the plurality of dies D0 are covered with the chemical liquid L2. That is, also in step S4, the chemical liquid L2 is deposited on the main surface Wa of the substrate W in a state where the rotation speed of the substrate W is low. The rotation speed of the substrate W is set to a value at which the chemical liquid L2 is not scattered to the inner peripheral surface of the guard 61, for example. As described above, since the chemical liquid L2 is deposited on the main surface Wa of the substrate W rotating at a low speed, liquid splashing of the chemical liquid L2 can be suppressed.

Moreover, in the present embodiment, the liquid film of the rinse liquid L1 is formed on the main surface Wa of the substrate W in step S3 immediately before step S4. Therefore, at the start of step S4, the chemical liquid L2 from the first nozzle 3 is deposited on the liquid film of the rinse liquid L1. Therefore, the chemical liquid L2 is not directly deposited on the corner portion of the die D0, and it is possible to further suppress liquid splashing of the chemical liquid L2. In addition, since the chemical liquid L2 flows together with the rinse liquid L1 on the main surface Wa of the substrate W, the chemical liquid L2 can spread with high fluidity from the initial stage of step S4.

For comparison, a case where the chemical liquid L2 is supplied to the main surface Wa of the substrate W in a dry state will be described. In this case, since the chemical liquid L2 can be directly deposited on the corner portion of the die D0, liquid splashing occurs. The droplets of the chemical liquid L2 that has splashed may be deposited at a random position on the main surface Wa of the substrate W. Therefore, the chemical liquid L2 starts to act on the main surface Wa at an unintended position. Further, the chemical liquid L2 non-uniformly flows on the main surface Wa due to the deep irregularities of the main surface Wa. A position where the medicinal liquid L2 quickly reaches and a position where it is less likely for the medicinal liquid L2 to reach locally appear due to such a liquid splashing or a non-uniform flow. At the position where the chemical liquid L2 quickly reaches, the chemical liquid L2 starts to act on the main surface Wa at a faster timing than at other positions. On the other hand, at a position where the chemical liquid L2 is less likely to reach, the chemical liquid L2 starts to act on the main surface Wa at a later timing than at other positions. That is, a large variation occurs in the distribution of the start timing with respect to the main surface Wa of the substrate W. As a result, substantial chemical liquid processing starts non-uniformly on the main surface Wa of the substrate W.

On the other hand, in the present embodiment, the chemical liquid L2 is deposited on the liquid film of the rinse liquid L1 on the main surface Wa of the substrate W rotating at a low speed. Therefore, liquid splashing of the chemical liquid L2 is less likely to occur, and the chemical liquid L2 spreads more uniformly on the main surface Wa with high fluidity. Therefore, replacement of the rinse liquid L1 with the chemical liquid L2 is performed more uniformly. That is, variations in start timing can be reduced. In other words, the processing unit 1 can more uniformly start the chemical liquid processing on the main surface (for example, the die D0) of the substrate W.

In the specific example described above, the chemical liquid L2 is dispensed from the plurality of dispense ports 3a of the first nozzle 3 in step S4. In this case, the chemical liquid L2 can be more uniformly supplied to the main surface Wa of the substrate W. Therefore, the processing unit 1 can more uniformly perform the chemical liquid processing on the substrate W.

Further, in the specific example described above, the chemical liquid L2 is dispensed from the plurality of dispense ports 3a toward the main surface Wa of the substrate W in a state where the plurality of dispense ports 3a is arranged substantially in the radial direction. In this case, it is possible to more effectively reduce the variation in the start timing at each position on the straight line in the radial direction.

In the specific example described above, in step S4, the first nozzle 3 reciprocates within a predetermined movement range. In this case, the liquid landing position of each dispense port 3a varies with time. As a result, the processing unit 1 can more uniformly supply the chemical liquid L2 to the main surface Wa of the substrate W, and further uniformly perform the chemical liquid processing on the substrate W.

In the specific example described above, the first nozzle 3 continues to dispense the chemical liquid L2 even after the rinse liquid L1 on the main surface Wa of the substrate W is replaced with the chemical liquid L2 in step S4. Therefore, the processing unit 1 can perform the chemical liquid processing on the substrate W with a higher throughput while suppressing insufficiency of processing.

In the specific example described above, the same first nozzle 3 is used in steps S3 and S4. Therefore, it is not necessary to switch the nozzle, and the processing is simple.

In the specific example described above, in step S5 (post-paddle step), the processing unit 1 causes the first nozzle 3 to dispense the rinse liquid L1 toward the main surface Wa of the substrate W while rotating the substrate W at a rotation speed at which the surfaces of the plurality of dies D0 are covered with the rinse liquid L1. The rotation speed of the substrate W is set to a value at which the processing liquid is not scattered to the inner peripheral surface of the guard 61, for example. As described above, since the rinse liquid L1 is deposited on the main surface Wa of the substrate W rotating at a low speed, liquid splashing of the rinse liquid L1 can be suppressed.

If the rinse liquid L1 is deposited on the liquid film of the chemical liquid L2 and is bounced back, the chemical liquid L2 may be entrained within the rinse liquid L1, resulting in upward splashing. Thus, the chemical liquid L2 may act non-uniformly on the main surface Wa of the substrate W. On the other hand, in the specific example described above, liquid splashing of the rinse liquid L1 can be suppressed in step S5. Therefore, the processing unit 1 can more uniformly replace the processing liquid on the main surface Wa of the substrate W from the chemical liquid L2 with the rinse liquid L1.

In the specific example described above, step S6 (replacement promotion step) is performed. The rotation speed of the substrate W in step S6 is set higher than the rotation speed of the substrate W in steps S3 to S5. As a specific example, the rotation speed of the substrate W in step S6 may be set to a value at which the processing liquid scattered from the peripheral edge of the substrate W reaches the inner peripheral surface of the guard 61. According to the increase in the rotation speed of the substrate W, even if the chemical liquid L2 remains on the main surface Wa of the substrate W in step S5, the chemical liquid L2 can be more reliably scattered from the peripheral edge of the substrate W in step S6.

In the specific example described above, in step S6, the second nozzle 5 dispenses the rinse liquid L1 toward the central portion of the main surface Wa of the substrate W. Thus, since the rinse liquid L1 pushes the chemical liquid L2 on the main surface Wa of the substrate W to flow radially outward from the central portion, the chemical liquid L2 can be more reliably scattered from the peripheral edge of the substrate W.

### <Chemical Liquid Processing Time>

Since the rotation speed of the substrate W in step S4 (chemical liquid paddle step) is low, the deviation between the rotation position of the substrate W at the time point when the first nozzle 3 starts dispensing the chemical liquid L2 and the rotation position of the substrate W at the time point when the first nozzle 3 stops dispensing the chemical liquid L2 greatly affects the uniformity of the chemical liquid processing. A specific description will be given below. In the following description, for the sake of simplicity, it is assumed that the first nozzle 3 is not reciprocated in step S4.

FIG. 12 is a plan view illustrating a positional relationship between the first nozzle 3 and the substrate W. In FIG. 12, the rotation direction of the substrate W is indicated by an arrow. In the example of FIG. 12, the substrate W rotates counterclockwise. FIG. 12 illustrates a virtual start line VL1 connecting liquid landing positions where the chemical liquid L2 is first deposited and a virtual end line VL2 connecting liquid landing positions where the chemical liquid L2 is last deposited. When the first nozzle 3 starts dispensing the chemical liquid L2 from the plurality of dispense ports 3a, the chemical liquid L2 is first deposited at each liquid landing position on the start line VL1, and subsequently is deposited at each position on the upstream side in the rotation direction with the rotation of the substrate W. That is, each liquid landing position relatively moves on a ring-shaped trajectory CLI centered on the rotation axis Q1 toward the upstream side in the rotation direction on the main surface Wa of the substrate W. When the chemical liquid processing time T has elapsed, the first nozzle 3 stops dispensing the chemical liquid L2 from the plurality of dispense ports 3a. Thus, the last chemical liquid L2 is deposited at each liquid landing position on the end line VL2.

The main surface Wa of the substrate W is divided into a region R1 and a region R2 by the start line VL1 and the end line VL2. The region R1 is a region on the upstream side in the rotation direction with respect to the start line VL1. In other words, the end on the downstream side in the rotation direction of the region R1 is the start line VL1, and the end on the upstream side in the rotation direction is the end line VL2. The region R2 is a region on the upstream side in the rotation direction with respect to the end line VL2.

Since each position on the region R1 passes immediately below the first nozzle 3 one more time than the region R2, the chemical liquid L2 is supplied to the region R1 more than to the region R2. Therefore, there may be a difference in the degree of processing with the chemical liquid L2 between the region R1 and the region R2. In particular, in the present embodiment, since the rotation speed of the substrate W in step S4 is low, the difference is relatively large. When the start line VL1 and the end line VL2 are the same, the entire main surface Wa of the substrate W corresponds to the region R1, and thus, the uniformity of the chemical liquid processing can be maximized. Conversely, when the start line VL1 and the end line VL2 are arranged on one straight line, the areas of the region R1 and the region R2 become the same, and the uniformity of the chemical liquid processing is the lowest.

The circumferential position of the start line VL1 is defined by the rotation position of the substrate W at the timing when the first nozzle 3 starts dispensing the chemical liquid L2, and the circumferential position of the end line VL2 is defined by the rotation position of the substrate W at the timing when the first nozzle 3 stops dispensing the chemical liquid L2. That is, the relative positions of the start line VL1 and the end line VL2 depend on the chemical liquid processing time T for dispensing the chemical liquid L2 and the rotation speed of the substrate W.

Therefore, the chemical liquid processing time T may be set according to the rotation speed of the substrate W. In other words, the chemical liquid processing time T may be set according to a unit time ΔT required for one rotation of the substrate W. Specifically, the chemical liquid processing time T may be set so as to satisfy the following Formula (1).

$$\vert T - n \cdot Δ T \vert / Δ T \leq α \qquad ( 1 )$$

Here, n is an integer and indicates the number of times (decimal point is rounded down) that the substrate W rotates within the chemical liquid processing time T. α is set to, for example, 0.25 or less. According to Formula (1), the chemical liquid processing time T is set such that the difference between the chemical liquid processing time T and the integral multiple of the unit time ΔT (=n·ΔT) is ¼ or less of the unit time ΔT. For example, a may be set to 0.2 or 0.1. As a is set smaller, the difference (angle) between the start line VL1 and the end line VL2 can be made smaller. That is, the smaller α is set, the more the uniformity of the chemical liquid processing can be improved. When α is zero, the chemical liquid processing time T is set to an integral multiple of the unit time ΔT. The chemical liquid processing time T may be set in advance and stored in the storage unit 921, for example.

### <Nozzle in Post-Paddle Step>

In the specific example described above, the chemical liquid L2 is dispensed from the first nozzle 3 in step S4 (chemical liquid paddle step), and the rinse liquid L1 is similarly dispensed from the first nozzle 3 in step S5 (post-paddle step). That is, the nozzles used in steps S4 and S5 are both the first nozzle 3. According to this, as described below, the processing unit 1 can more uniformly perform the chemical liquid processing on the main surface Wa of the substrate W.

First, a state in which the chemical liquid L2 starts to be deposited on the main surface Wa of the substrate W at the initial stage of step S4 will be described. In the specific example described above, the first nozzle 3 dispenses the chemical liquid L2 from the plurality of dispense ports 3a arranged in the radial direction. Moreover, in the present embodiment, the chemical liquid L2 dispensed from the plurality of dispense ports 3a is deposited on the liquid film of the rinse liquid L1 (see also FIG. 11). Therefore, the chemical liquid L2 can quickly spread from each liquid landing position. Therefore, the chemical liquid L2 is supplied to each position on the straight line in the radial direction of the main surface Wa of the substrate W with a very small time difference. Therefore, here, for simplicity of description, it is assumed that the chemical liquid L2 is simultaneously supplied on the straight line.

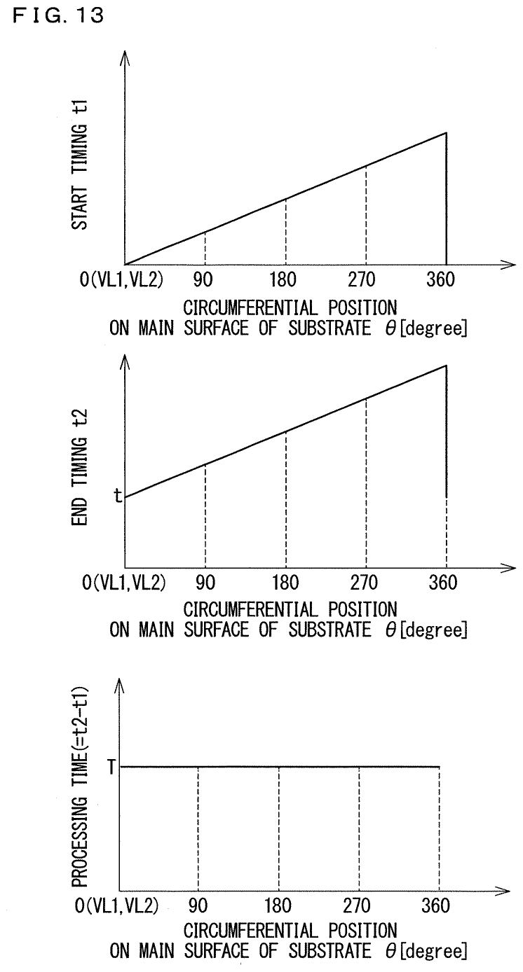

When the position on the main surface Wa of the substrate W passes immediately below the first nozzle 3, the chemical liquid L2 is deposited at the position. Therefore, a start timing t1 at which the chemical liquid L2 starts to be supplied to each position is delayed toward the position on the upstream side in the rotation direction from the start line VL1. FIG. 13 is a graph illustrating the start timing t1, an end timing t2, and a substantial processing time at each position in the circumferential direction on the main surface Wa of the substrate W. The end timing t2 and the processing time will be described in detail later. In the example of FIG. 13, each position in the circumferential direction on the main surface Wa of the substrate W is indicated by an angle θ (see also FIG. 12), the start line VL1 is set to 0 degrees, and the direction toward the upstream side in the rotation direction is set to be positive.

As illustrated in FIG. 13, the start timing t1 is later at a position farther from the start line VL1 toward the upstream side in the rotation direction. The start timing t1 is a proportionality coefficient corresponding to the rotation speed of the substrate W and is proportional to the circumferential position. The lower the rotation speed of the substrate W, the larger the proportionality coefficient. That is, as in the present embodiment, when the rotation speed of the substrate W is low, the difference between the start timing t1 at the start line VL1 and the start timing t1 at the position immediately downstream of the start line VL1 in the rotation direction becomes larger.

The action of the chemical liquid L2 on each position on the main surface Wa of the substrate W is substantially terminated by the supply of the rinse liquid L1 in step S5 (post-paddle step). Therefore, the timing at which the rinse liquid L1 starts to be deposited can be easily grasped as the end timing t2. In the specific example described above, in step S5, the first nozzle 3 dispenses the rinse liquid L1 from the plurality of dispense ports 3a arranged in the radial direction. Therefore, here, for simplicity of description, it is assumed that the rinse liquid L1 is simultaneously supplied to each position on the straight line in the radial direction of the main surface Wa of the substrate W.

In the example of FIG. 13, the end line VL2 is set to 0 degrees. That is, the start line VL1 and the end line VL2 are the same. The rinse liquid L1 from the first nozzle 3 is first deposited on the end line VL2 (=start line VL1). With the rotation of the substrate W, the rinse liquid L1 is gradually deposited also at a portion away from the end line VL2 toward the upstream side in the rotation direction, and thus, the rinse liquid L1 is deposited at a later timing at a position farther from the end line VL2 toward the upstream side in the rotation direction. Therefore, as illustrated in FIG. 13, the end timing t2 is slower at a position farther from the end line VL2 on the upstream side in the rotation direction. The end timing t2 is a proportionality coefficient corresponding to the rotation speed of the substrate W and is proportional to the circumferential position. The lower the rotation speed of the substrate W, the larger the proportionality coefficient.

The substantial processing time at each position on the main surface Wa of the substrate W is a time (=t2−t1) between the end timing t2 and the start timing t1 at the same position. As described above, since the start timing t1 is later as the position is closer to the upstream side in the rotation direction and the end timing t2 is also later as the position is closer to the upstream side in the rotation direction, it is possible to reduce the variation in the substantial processing time (=t2−t1) at each position.

As described above, in steps S4 and S5, the processing unit 1 causes the same first nozzle 3 to dispense the chemical liquid L2 and the rinse liquid L1, respectively. Therefore, it is possible to reduce the variation in the distribution on the main surface Wa of the substantial processing time. Therefore, the processing unit 1 can more uniformly perform the chemical liquid processing on the substrate W.

If the rotation speeds (for example, the target values) of the substrate W in steps S4 and S5 are the same, ideally, the variation in the substantial processing time can be eliminated. In the example of FIG. 13, the substantial processing time is illustrated constant regardless of the position on the main surface Wa of the substrate W. Note that both rotation speeds may not be completely the same and may be different. For example, the difference between the rotation speed (for example, the target value) of the substrate W in step S4 and the rotation speed (for example, the target value) of the substrate W in step S5 may be 50% or less, 20% or less, 10% or less, or 5% or less of the rotation speed of the substrate W in step S4. According to this, it is possible to more effectively reduce the variation in substantial processing time.

In the transition from step S4 to step S5, the control unit 90 may switch the opening and closing states of the chemical liquid valve 43 and the rinse valve 44 while continuing to open the valve 32. Accordingly, the first nozzle 3 can continuously dispense the rinse liquid L1 temporally following the chemical liquid L2. In other words, the opening and closing states of the chemical liquid valve 43 and the rinse valve 44 may be switched within a time difference that allows the first nozzle 3 to continuously dispense the rinse liquid L1 to the chemical liquid L2. When the first nozzle 3 continuously dispenses the rinse liquid L1 to the chemical liquid L2, the rinse liquid L1 can be deposited with higher positional accuracy with respect to the end line VL2 where the chemical liquid L2 is finally deposited.

### <Flow Rate of Chemical Liquid and Rotation Speed of Substrate>

The flow rate of the chemical liquid L2 in step S4 (chemical liquid paddle step) may be set to be larger than the flow rate of the rinse liquid L1 in step S3 (pre-paddle step). Furthermore, the rotation speed of the substrate W in step S4 may be set to be higher than the rotation speed of the substrate W in step S3. That is, the rotation speed of the substrate W in step S4 may be set to be higher than the rotation speed of the substrate W in step S3 and lower than the rotation speed of the substrate W in step S7 (replacement promotion step).

Since the flow rate of the chemical liquid L2 is larger and the rotation speed of the substrate W is higher, the old chemical liquid L2 is quickly replaced with the new chemical liquid L2 on the main surface Wa of the substrate W. Moreover, when the new chemical liquid L2 is supplied, the concentration distribution of the chemical liquid L2 on the main surface Wa of the substrate W can be made uniform. Therefore, the uniformity of the chemical liquid processing can be improved.

In addition, when the foreign substances are dispersed on the main surface Wa of the substrate W, the processing can be performed non-uniformly. On the other hand, when the flow rate of the chemical liquid L2 is larger and the rotation speed of the substrate W is higher, the foreign substances can be quickly removed from the main surface Wa of the substrate W. Therefore, the uniformity of the chemical liquid processing can be further improved.

### <Plurality of Chemical Liquid Processings>

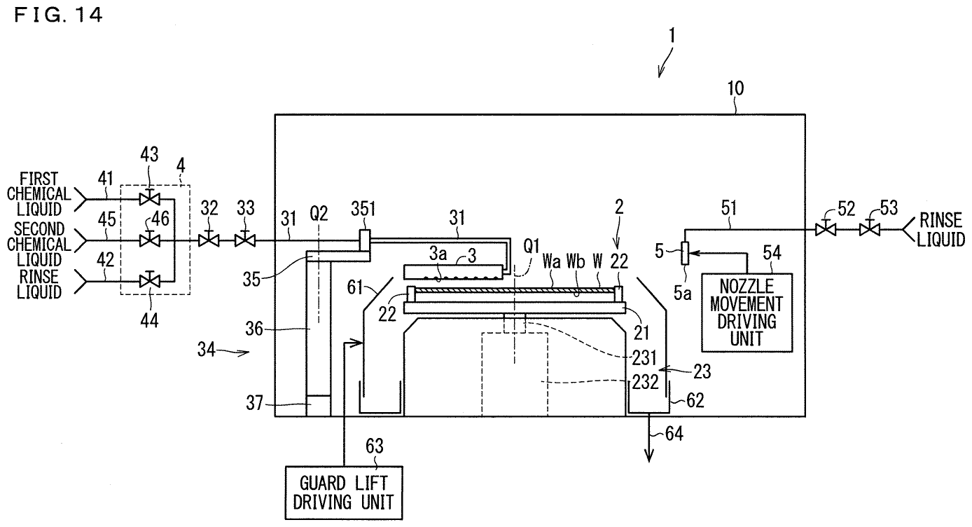

In the specific example described above, the processing unit 1 performs the chemical liquid processing using one type of chemical liquid, however, the chemical liquid processing using a plurality of types of chemical liquids may be sequentially performed on the substrate W. FIG. 14 is a diagram schematically illustrating a second example of the configuration of the processing unit 1 according to the first embodiment. In the example of FIG. 14, the processing unit 1 is configured to be able to selectively supply the first chemical liquid (for example, hydrofluoric acid), the second chemical liquid (for example, a mixed liquid of sulfuric acid and hydrogen peroxide water), and the rinse liquid to the substrate W. Specifically, the switching unit 4 is connected not only to the upstream end of the liquid supply pipe 31, the downstream end of the chemical liquid supply pipe 41, and the downstream end of the rinse liquid supply pipe 42, but also to the downstream end of the chemical liquid supply pipe 45. The switching unit 4 switches a pipe communicating with the liquid supply pipe 31 among the chemical liquid supply pipe 41, the chemical liquid supply pipe 45, and the rinse liquid supply pipe 42. The upstream end of the chemical liquid supply pipe 41 is connected to a first chemical liquid supply source (not illustrated), and the upstream end of the chemical liquid supply pipe 45 is connected to a second chemical liquid supply source (not illustrated). The first chemical liquid and the second chemical liquid are different types of chemical liquids.

The switching unit 4 may be, for example, a multi-valve. Specifically, the switching unit 4 may include not only the chemical liquid valve 43 and the rinse valve 44 but also the chemical liquid valve 46. When the chemical liquid valve 43 is opened, the chemical liquid supply pipe 41 communicates with the liquid supply pipe 31. When the rinse valve 44 is opened, the rinse liquid supply pipe 42 communicates with the liquid supply pipe 31. When the chemical liquid valve 46 is opened, the chemical liquid supply pipe 45 communicates with the liquid supply pipe 31. These valves are controlled by the control unit 90.

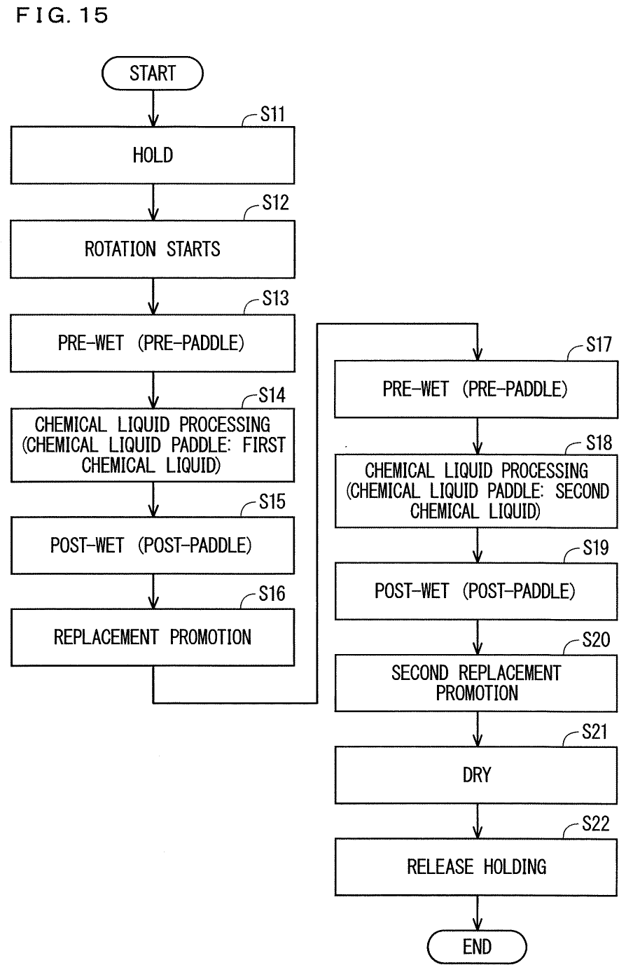

FIG. 15 is a flowchart illustrating a second example of the substrate processing according to the first embodiment. First, as in step S1, the substrate W is carried into the processing unit 1, and the substrate holding unit 2 holds the substrate W (step S11: holding step). Next, as in step S2, the substrate holding unit 2 starts rotation of the substrate W (step S12: rotation start process).

Next, as in step S3, the processing unit 1 supplies the rinse liquid to the main surface Wa of the substrate W rotating at a low speed to form the liquid film of the rinse liquid on the main surface Wa of the substrate W (step S13: pre-wet step (pre-paddle step)). Next, as in step S4, the processing unit 1 causes the first nozzle 3 to dispense the first chemical liquid toward the main surface Wa of the substrate W rotating at a low speed (step S14: chemical liquid processing step (chemical liquid paddle step)). As a result, a liquid film of the first chemical liquid is formed on the main surface Wa of the substrate W, and the first chemical liquid acts on the main surface of the substrate W. That is, a processing corresponding to the first chemical liquid is performed on the substrate W (for example, the die D0). Next, as in step S5, the processing unit 1 supplies the rinse liquid to the main surface Wa of the substrate W rotating at a low speed (step S15: post-wet step (post-paddle step)). Thus, the first chemical liquid on the main surface Wa of the substrate W is replaced with the rinse liquid. Here, in step S15, since the rotation speed of the substrate W is low, the first chemical liquid may slightly remain on the main surface Wa of the substrate W. Then, similarly to step S6, the processing unit 1 causes the second nozzle 5 to dispense the rinse liquid toward the central portion of the main surface Wa of the substrate W while increasing the rotation speed of the substrate W (step S16: replacement promotion step). Thus, the first chemical liquid remaining on the main surface Wa of the substrate W can be more reliably replaced with the rinse liquid.

In step S16, since the rotation speed of the substrate W is higher than the rotation speed of the substrate W in steps S13 to S15, the liquid film of the rinse liquid on the main surface Wa of the substrate W becomes thin, and at least a part of the upper surface of the die D0 of the substrate W may be exposed. In other words, the rotation speed of the substrate W in the replacement promotion step may be set to a value at which at least a part of the upper surface of the die D0 on the main surface Wa of the substrate W is dispensed.

Therefore, in the example of FIG. 15, as in step S3, the processing unit 1 reduces the rotation speed of the substrate W, supplies the rinse liquid to the main surface Wa of the substrate W rotating at a low speed again, and forms the liquid film of the rinse liquid on the main surface Wa of the substrate W (step S17: pre-paddle step). Thus, the processing unit 1 can form the liquid film of the rinse liquid covering the surfaces of the plurality of dies D0 again on the main surface Wa of the substrate W. Next, as in step S4, the processing unit 1 causes the first nozzle 3 to dispense the second chemical liquid toward the main surface Wa of the substrate W rotating at a low speed (step S18: chemical liquid paddle step). Thus, a liquid film of the second chemical liquid is formed on the main surface Wa of the substrate W, and the second chemical liquid acts on the main surface Wa of the substrate W. That is, the processing according to the second chemical liquid is performed on the main surface Wa (for example, the die D0) of the substrate W. Next, as in step S5, the processing unit 1 supplies the rinse liquid to the main surface Wa of the substrate W rotating at a low speed (step S19: post-paddle step). Thus, the second chemical liquid on the main surface Wa of the substrate W is replaced with the rinse liquid. Here, in step S19, since the rotation speed of the substrate W is low, the second chemical liquid may slightly remain on the main surface Wa of the substrate W. Then, similarly to step S6, the processing unit 1 causes the second nozzle 5 to dispense the rinse liquid toward the central portion of the main surface Wa of the substrate W while increasing the rotation speed of the substrate W (step S20: replacement promotion step). Thus, the second chemical liquid remaining on the main surface Wa of the substrate W can be more reliably replaced with the rinse liquid.

Next, as in step S7, the processing unit 1 increases the rotation speed of the substrate W and dries the substrate W (step S21: drying step). Next, as in step S8, the processing unit 1 releases the holding of the substrate W (holding releasing step), and the center robot 122 carries out the substrate W.

As described above, the processing unit 1 can perform the first chemical liquid processing corresponding to the first chemical liquid and the second chemical liquid processing corresponding to the second chemical liquid on the substrate W in this order. That is, the processing unit 1 performs one set of processing of step S3 (pre-paddle step), step S4 (chemical liquid paddle step), step S5 (post-paddle step), and step S6 (replacement promotion step) a plurality of times. Here, in each step S4, the processing unit 1 supplies different types of chemical liquids to the main surface Wa of the substrate W. When three or more types of chemical liquid processing are performed, the processing unit 1 repeatedly performs the one set of processing three or more times.

### Second Embodiment

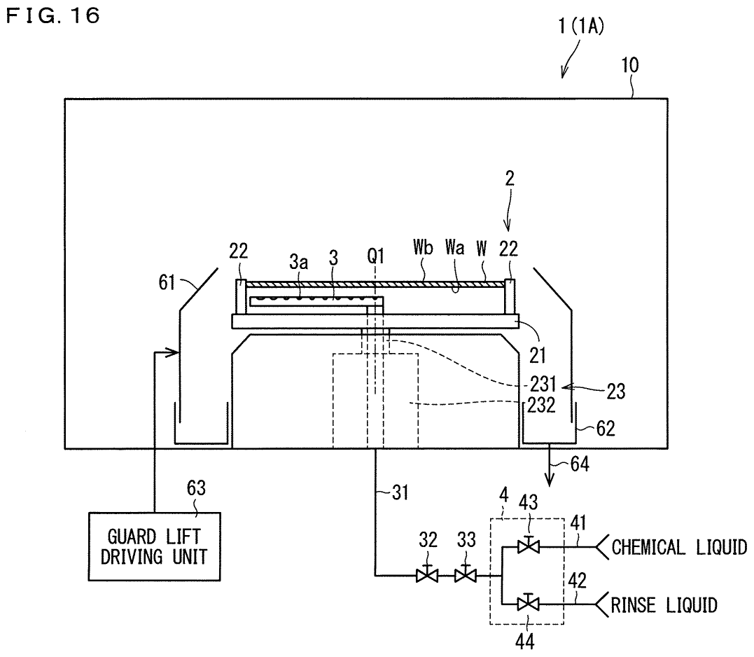

FIG. 16 is a diagram schematically illustrating an example of a configuration of the processing unit 1 according to the second embodiment. Hereinafter, the processing unit 1 according to the second embodiment is also referred to as processing unit 1A. The processing unit 1A is different from the processing unit 1 in, for example, the posture of the substrate W and the position of the first nozzle 3. In the example of FIG. 16, the processing unit 1A is not provided with the second nozzle 5.

As illustrated in FIG. 16, in the processing unit 1A, the substrate holding unit 2 holds the substrate W in a posture in which the main surface Wa faces vertically downward. That is, in the second embodiment, the substrate W is carried into the processing unit 1A by the center robot 122 in a posture in which the main surface Wa of the substrate W faces vertically downward, and the substrate holding unit 2 receives the substrate W in the posture and holds the substrate W.

In the processing unit 1A, the first nozzle 3 is positioned vertically below the substrate W held by the substrate holding unit 2. In the example of FIG. 16, the first nozzle 3 is provided between the main surface Wa of the substrate W and the spin base 21. The first nozzle 3 dispenses the processing liquid toward the main surface Wa of the substrate W held by the substrate holding unit 2. In the example of FIG. 16, the first nozzle 3 extends in a direction along the main surface Wa of the substrate W, and a plurality of dispense ports 3a is formed on the upper portion of the first nozzle 3. In the example of FIG. 16, the first nozzle 3 extends in the radial direction with respect to the rotation axis Q1. The plurality of dispense ports 3a is arranged at intervals in the longitudinal direction (that is, the radial direction) of the first nozzle 3. The plurality of dispense ports 3a may be arranged in one row. The number of the dispense ports 3a is not particularly limited, and may be, for example, 10 or more or 15 or more. The dispense port 3a may have, for example, a circular shape in plan view, and the diameter of the dispense port 3a may be set to, for example, about several mm.

The first nozzle 3 can selectively dispense the chemical liquid and the rinse liquid as the processing liquid. In the example of FIG. 16, the first nozzle 3 is connected to the downstream end of the liquid supply pipe 31. In the example of FIG. 16, the shaft 231 is a hollow shaft, and a through hole penetrating the spin base 21 in the vertical direction is formed in the central portion of the spin base 21. The through hole communicates with the hollow portion of the shaft 231. The liquid supply pipe 31 penetrates the hollow portion of the shaft 231 and the spin base 21, and the upper end (downstream end) of the liquid supply pipe 31 protrudes vertically upward from the spin base 21. The upper end of the liquid supply pipe 31 is connected to the first nozzle 3. The first nozzle 3 extends radially outward from the upper end of the liquid supply pipe 31. The lower end (upstream end) of the liquid supply pipe 31 is connected to the switching unit 4, and the switching unit 4 is also connected to the downstream end of the chemical liquid supply pipe 41 and the downstream end of the rinse liquid supply pipe 42. The upstream end of the chemical liquid supply pipe 41 is connected to the chemical liquid supply source, and the upstream end of the rinse liquid supply pipe 42 is connected to the rinse liquid supply source. The switching unit 4 is controlled by the control unit 90 to switch the pipe communicating with the liquid supply pipe 31 between the chemical liquid supply pipe 41 and the rinse liquid supply pipe 42.

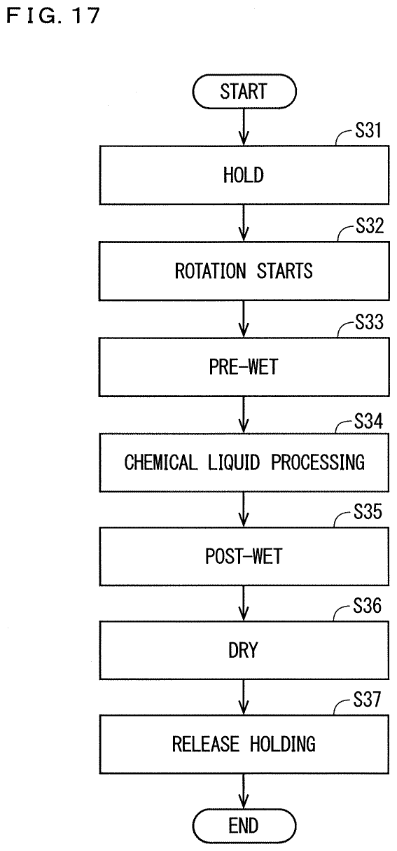

The circumferential moving speed of each position of the main surface Wa during rotation of the substrate W increases toward the radially outer side. Therefore, the first nozzle 3 may dispense the processing liquid to the peripheral region on the radially outer side of the main surface Wa at a flow rate larger than the flow rate to the central region on the radially inner side of the main surface Wa of the substrate W. In the example of FIG. 17, the opening area of the dispense port 3a located radially outward is larger than the opening area of the dispense port 3a located radially inward. The opening area of each of the plurality of dispense ports 3a may increase toward the radially outer side in a monotonically non-decreasing manner. That is, the opening area of a certain dispense port 3a may be greater than or equal to the opening area of another dispense port 3a located radially inward relative to the certain dispense port 3a. According to this, since the first nozzle 3 can dispense the processing liquid at a flow rate larger than that in the central region with respect to the peripheral region having a high moving speed, the processing liquid can be more uniformly supplied to the main surface Wa of the substrate W.

Alternatively, the pitch between the adjacent dispense ports 3a of the first nozzle 3 may increase toward the radially outer side in a monotonically non-decreasing manner. That is, the pitch between two dispense ports 3a may be greater than or equal to the pitch between another two dispense ports 3a located radially inward relative to the two dispense ports 3a. According to this, since the first nozzle 3 can dispense the processing liquid at a large flow rate to the peripheral region having a high moving speed, the processing liquid can be more uniformly supplied to the main surface Wa of the substrate W. As a result, since the first nozzle 3 can dispense the processing liquid at a flow rate larger than that in the central region with respect to the peripheral region having a high moving speed, the processing liquid can be more uniformly supplied to the main surface Wa of the substrate W.

FIG. 17 is a flowchart illustrating an example of substrate processing according to the second embodiment. First, the center robot 122 carries the substrate W into the chamber 10 of the processing unit 1A, and the substrate holding unit 2 receives the substrate W and holds the substrate W (step S31: holding step). Here, the center robot 122 carries the substrate W into the chamber 10 in a posture in which the main surface Wa of the substrate W faces vertically downward. The substrate holding unit 2 holds the substrate W in a posture in which the main surface Wa faces vertically downward. The substrate holding unit 2 continues holding the substrate W until the processing on the substrate W is completed. Further, here, at the time of being carried into the chamber 10, the main surface Wa of the substrate W is generally in a dry state.

Next, the substrate holding unit 2 starts rotating the substrate W around the rotation axis Q1 (step S32). The substrate holding unit 2 may maintain the rotation of the substrate W until the processing on the substrate W is completed. After step S31, the guard lift driving unit 63 may raise the guard 61 to the upper position.

Next, the processing unit 1A supplies the rinse liquid to the main surface Wa of the substrate W (step S33: pre-wet step). Specifically, the control unit 90 opens the rinse valve 44 and the valve 32. Thus, the rinse liquid is dispensed from the plurality of dispense ports 3a of the first nozzle 3 in a continuous flow state. The flow rate of the rinse liquid and the rotation speed of the substrate W are set such that the surfaces of the dies D0 of the substrate W are covered with the rinse liquid. In the second embodiment, since the main surface Wa of the substrate W faces vertically downward, a portion having a large thickness of the liquid film of the rinse liquid is more likely to fall. Therefore, the thickness of the portion between the dies D0 of the liquid film of the rinse liquid may be less than the thickness of the die D0.

When a predetermined pre-time has elapsed since the start of the supply of the rinse liquid, the control unit 90 executes step S34 described later.

Next, the processing unit 1A supplies the chemical liquid to the main surface Wa of the substrate W (step S34: chemical liquid processing step). The control unit 90 closes the rinse valve 44 and opens the chemical liquid valve 43 and the valve 32. Thus, the chemical liquid is dispensed from the plurality of dispense ports 3a of the first nozzle 3 toward the main surface Wa of the substrate W in a continuous flow state. The flow rate of the chemical liquid and the rotation speed of the substrate W are set such that the surfaces of the dies D0 of the substrate W are covered with the chemical liquid. The thickness of the portion between the dies D0 of the liquid film of the chemical liquid may be less than the thickness of the dies D0.

Due to the supply of the chemical liquid, the processing liquid adhering to the main surface Wa is replaced from the rinse liquid with the chemical liquid. As in the first embodiment, the chemical liquid initially is deposited on the liquid film of the rinse liquid adhering to the main surface Wa of the substrate W. Therefore, the chemical liquid can spread on the main surface Wa more uniformly from the initial stage of step S34. Therefore, the processing unit 1A can more uniformly replace the rinse liquid with the chemical liquid, and the chemical liquid starts to more uniformly act on the main surface Wa of the substrate W. In other words, it is possible to reduce the variation in the distribution on the main surface Wa at the start timing at which the chemical liquid starts to act at each position on the main surface Wa of the substrate W.

As described above, when the first nozzle 3 dispenses the chemical liquid from the plurality of dispense ports 3a arranged in the radial direction, it is possible to effectively reduce the variation in start timing particularly in the radial direction.

When the processing with the chemical liquid is sufficiently performed, the processing unit 1A stops the supply of the chemical liquid. As a specific example, when a predetermined chemical liquid processing time has elapsed since the start of the supply of the chemical liquid, the control unit 90 executes step S35 described later.

Next, the processing unit 1A supplies the rinse liquid to the main surface Wa of the substrate W (step S35: post-wet step). Specifically, the control unit 90 closes the chemical liquid valve 43 and opens the rinse valve 44 and the valve 32. Thus, the rinse liquid is dispensed from the plurality of dispense ports 3a of the first nozzle 3 toward the main surface Wa of the substrate W in a continuous flow state. The flow rate of the rinse liquid and the rotation speed of the substrate W are set such that the surfaces of the dies D0 of the substrate W are covered with the rinse liquid. The thickness of the portion between the dies D0 of the liquid film of the rinse liquid may be less than the thickness of the die D0.

Due to the supply of the rinse liquid, the processing liquid adhering to the main surface Wa of the substrate W is replaced from the chemical liquid with the rinse liquid. Similarly to the first embodiment, the rinse liquid can spread on the main surface Wa more uniformly from the initial stage of step S35, and thus, the chemical liquid can be replaced with the rinse liquid more uniformly. By this replacement, the action of the chemical liquid at each position on the main surface Wa of the substrate W is substantially terminated. Therefore, it is possible to reduce the variation in the distribution on the main surface Wa at the stop timing at which the action of the chemical liquid at each position on the main surface Wa of the substrate W is terminated.

As described above, in step S35, the processing liquid adhering to the main surface Wa is replaced from the chemical liquid with the rinse liquid.

When the chemical liquid is sufficiently replaced with the rinse liquid, the processing unit 1A stops the supply of the rinse liquid. For example, when a predetermined post-time has elapsed since the start of the supply of the rinse liquid, the control unit 90 closes the rinse valve 44 and the valve 32. Thus, the supply of the rinse liquid from the first nozzle 3 is stopped.

Next, the processing unit 1A dries the substrate W (step S36: drying step). As a specific example, the substrate holding unit 2 further increases the rotation speed of the substrate W (so-called spin drying). The rotation speed of the substrate W may be set to, for example, more than 1200 rpm, 1500 rpm or more, or 2000 rpm or more. Since the rotation speed of the substrate W is higher than the rotation speed of the substrate W in steps S33 to S35, the amount of the processing liquid scattered from the peripheral edge of the substrate W can be increased. In addition, the evaporation of the processing liquid of the substrate W can be promoted by the airflow. Therefore, the substrate W can be dried more quickly.

When the substrate W is sufficiently dried, the processing unit 1 stops the rotation of the substrate W. For example, when a predetermined drying time has elapsed since the increase in the rotation speed, the substrate holding unit 2 stops the rotation of the substrate W.

Next, the substrate holding unit 2 releases the holding of the substrate W (step S37: holding releasing step). Specifically, the substrate holding unit 2 displaces the plurality of chuck pins 22 from the respective holding positions to the release positions. Thus, the holding of the substrate W is released. Next, the center robot 122 carries out the substrate W from the processing unit 1A.

As described above, the processing unit 1A can perform various types of processing on the substrate W whose main surface Wa has an uneven shape formed by the plurality of dies D0.

Moreover, in the processing unit 1A, the main surface Wa of the substrate W faces vertically downward, and the first nozzle 3 dispenses the processing liquid vertically upward from the plurality of dispense ports 3a to supply the processing liquid to the main surface Wa of the substrate W. Therefore, even when the processing liquid bounces back on the irregularities of the main surface Wa of the substrate W, the group of droplets of the processing liquid bounced back is directed toward the spin base 21. Therefore, the group of droplets hardly scatters outside the guard 61.

Also in the second embodiment, the liquid film of the rinse liquid is formed on the main surface Wa of the substrate W in step S33 immediately before step S34. Therefore, at the start of step S34, the chemical liquid from the first nozzle 3 is deposited on the liquid film of the rinse liquid. Therefore, the chemical liquid is not directly deposited on the corner portion of the die D0, and flows together with the rinse liquid on the main surface Wa of the substrate W. Therefore, the chemical liquid can spread with high fluidity from the initial stage of step S34. Therefore, the replacement of the rinse liquid with the chemical liquid is more uniformly performed. That is, variations in start timing can be reduced. In other words, the processing unit 1A can more uniformly start the chemical liquid processing on the main surface Wa (for example, the die D0) of the substrate W.

In the specific example described above, the chemical liquid is dispensed from the plurality of dispense ports 3a of the first nozzle 3 in step S34. In this case, the chemical liquid can be more uniformly supplied to the main surface Wa of the substrate W. Therefore, the processing unit 1A can more uniformly perform the chemical liquid processing on the substrate W.

### Third Embodiment

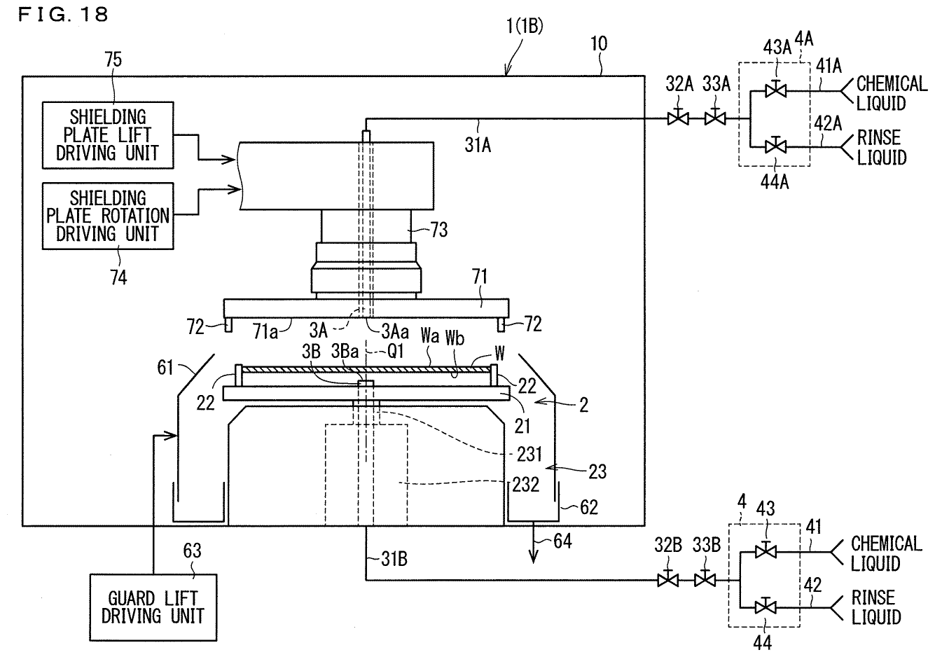

FIG. 18 is a diagram schematically illustrating an example of a configuration of the processing unit 1 according to the third embodiment. Hereinafter, the processing unit 1 according to the third embodiment is also referred to as processing unit 1B. The processing unit 1B is different from the processing unit 1 in the configuration of dispensing the processing liquid and the presence or absence of a shielding plate 71.

The processing unit 1B is provided with a nozzle 3A and a nozzle 3B, each of which is one example of the first nozzle 3. The nozzle 3B is provided vertically below the substrate W held by the substrate holding unit 2. In the third embodiment, for example, the substrate holding unit 2 holds the substrate W in a state where the main surface Wa faces vertically upward. In the example of FIG. 18, the nozzle 3B is provided at a position facing the central portion of the substrate W in the vertical direction. Specifically, the nozzle 3B protrudes vertically upward from a through hole provided in the central portion of the spin base 21. The nozzle 3B has the dispense port 3a at the upper end of the nozzle 3B, and dispenses the processing liquid vertically upward from the dispense port 3a, that is, toward the central portion of the main surface Wb of the substrate W.

The nozzle 3B is connected to the downstream end of the liquid supply pipe 31B. In the example of FIG. 18, the shaft 231 is a hollow shaft, and the liquid supply pipe 31B penetrates the spin base 21 and the shaft 231 in the vertical direction similarly to the liquid supply pipe 31 of the processing unit 1A. The lower end (upstream end) of the liquid supply pipe 31B is connected to a switching unit 4B, and the switching unit 4B is also connected to the downstream end of the chemical liquid supply pipe 41B and the downstream end of the rinse liquid supply pipe 42B. The upstream end of the chemical liquid supply pipe 41B is connected to a chemical liquid supply source, and the upstream end of the rinse liquid supply pipe 42B is connected to the rinse liquid supply source. The switching unit 4B is controlled by the control unit 90 to switch the pipe communicating with the liquid supply pipe 31B between the chemical liquid supply pipe 41B and the rinse liquid supply pipe 42B.

The switching unit 4B may be, for example, a multi-valve. Specifically, the switching unit 4B may include a chemical liquid valve 43B and a rinse valve 44B. These valves are controlled by the control unit 90. When the chemical liquid valve 43B is opened, the chemical liquid supply pipe 41B communicates with the liquid supply pipe 31B. When a valve 32B described later is opened in this state, the chemical liquid from the chemical liquid supply source is supplied to the nozzle 3B through the chemical liquid supply pipe 41B, the switching unit 4B, and the liquid supply pipe 31B, and is dispensed from the nozzle 3B. When the rinse valve 44B is opened, the rinse liquid supply pipe 42B communicates with the liquid supply pipe 31B. When the valve 32B described later is opened in this state, the rinse liquid from the rinse liquid supply source is supplied to the nozzle 3B through the rinse liquid supply pipe 42B, the switching unit 4B, and the liquid supply pipe 31B, and is dispensed from the nozzle 3B.

The valve 32B and a flow rate adjusting valve 33B are interposed in the liquid supply pipe 31B. When the valve 32B is opened, the processing liquid is dispensed from the nozzle 3B, and when the valve 32B is closed, the dispense of the processing liquid from the nozzle 3B is stopped. The flow rate adjusting valve 33B adjusts the flow rate of the processing liquid flowing through the liquid supply pipe 31B. The flow rate adjusting valve 33B may be a mass flow controller. The valve 32B and the flow rate adjusting valve 33B are controlled by the control unit 90.

The shielding plate 71 is also referred to as opposing plate. The shielding plate 71 is provided vertically above the substrate holding unit 2 and faces the substrate holding unit 2 in the vertical direction. The shielding plate 71 has, for example, a disk shape, and an opposing surface 71a as the lower surface of the shielding plate 71 faces the substrate holding unit 2 in the vertical direction. The opposing surface 71a of the shielding plate 71 may be a flat surface, and is, for example, parallel to a horizontal plane. The opposing surface 71a has, for example, a circular shape in plan view. The opposing surface 71a may be greater than or equal to the diameter of the substrate W.

In the example of FIG. 18, the shielding plate 71 also has a function of holding the substrate W. Specifically, a plurality of chuck pins 72 is provided on the opposing surface 71a of the shielding plate 71. The plurality of chuck pins 72 protrudes vertically downward from the opposing surface 71a. The plurality of chuck pins 72 is provided, for example, at equal intervals in the circumferential direction with respect to the rotation axis Q1. The plurality of chuck pins 72 is provided in a manner of being displaceable between holding positions and release positions described next. The holding position is a position where the chuck pin 72 abuts on the peripheral edge of the substrate W. When the plurality of chuck pins 72 stops at the respective holding positions, the plurality of chuck pins 72 holds the substrate W. Therefore, the holding position of each chuck pin 72 is located on the circumference having the same diameter as the substrate W. The release position is a position where each chuck pin 72 is separated from the substrate W. That is, the release position of each chuck pin 72 is located on a circumference having a diameter which is larger than the diameter of the substrate W. When the plurality of chuck pins 72 stops at the respective release positions, the holding of the substrate W by the chuck pins 72 is released. In the example of FIG. 18, the chuck pins 72 located at the release positions are illustrated. The position in the radial direction of the chuck pin 72 located at the release position is radially outward from the chuck pin 22 located at the holding position. The position in the radial direction of the chuck pin 72 located at the holding position is radially inward from the chuck pin 22 located at the release position. The processing unit 1B is provided with a pin driving unit (not illustrated) that displaces the chuck pin 72. The pin driving unit includes a driving source such as a motor or an air cylinder, and is controlled by the control unit 90.

In the example of FIG. 18, a support shaft 73 is provided on the upper surface of the shielding plate 71. The support shaft 73 is provided, for example, on the rotation axis Q1. A through hole extending along the rotation axis Q1 is formed in the support shaft 73 and the shielding plate 71, and the liquid supply pipe 31A is disposed in the through hole. The nozzle 3A is connected to the lower end of the liquid supply pipe 31A. The nozzle 3A is provided at a position facing the central portion of the substrate W. The nozzle 3A has a dispense port 3Aa at the lower end of the nozzle 3A, and dispenses the processing liquid from the dispense port 3Aa.

The upstream end of the liquid supply pipe 31A is connected to a switching unit 4A, and the switching unit 4A is also connected to the downstream end of a chemical liquid supply pipe 41A and the downstream end of a rinse liquid supply pipe 42A. The upstream end of the chemical liquid supply pipe 41A is connected to the chemical liquid supply source, and the upstream end of the rinse liquid supply pipe 42A is connected to the rinse liquid supply source. The switching unit 4A is controlled by the control unit 90 to switch the pipe communicating with the liquid supply pipe 31A between the chemical liquid supply pipe 41A and the rinse liquid supply pipe 42A.

The switching unit 4A may be, for example, a multi-valve. Specifically, the switching unit 4A may include a chemical liquid valve 43A and a rinse valve 44A. These valves are controlled by the control unit 90. When the chemical liquid valve 43A is opened, the chemical liquid supply pipe 41A communicates with the liquid supply pipe 31A. When a valve 32A described later is opened in this state, the chemical liquid from the chemical liquid supply source is supplied to the nozzle 3A through the chemical liquid supply pipe 41A, the switching unit 4A, and the liquid supply pipe 31A, and is dispensed from the nozzle 3A. When the rinse valve 44A is opened, the rinse liquid supply pipe 42A communicates with the liquid supply pipe 31A. When the valve 32A described later is opened in this state, the rinse liquid from the rinse liquid supply source is supplied to the nozzle 3A through the rinse liquid supply pipe 42A, the switching unit 4A, and the liquid supply pipe 31A, and is dispensed from the nozzle 3A.

The valve 32A and a flow rate adjusting valve 33A are interposed in the liquid supply pipe 31A. When the valve 32A is opened, the processing liquid is dispensed from the nozzle 3A, and when the valve 32A is closed, the dispense of the processing liquid from the nozzle 3A is stopped. The flow rate adjusting valve 33A adjusts the flow rate of the processing liquid flowing through the liquid supply pipe 31A. The flow rate adjusting valve 33A may be a mass flow controller. The valve 32A and the flow rate adjusting valve 33A are controlled by the control unit 90.

In the example of FIG. 18, the processing unit 1B is provided with a shielding plate lift driving unit 75 and a shielding plate rotation driving unit 74. The shielding plate lift driving unit 75 integrally raises and lowers the shielding plate 71, the nozzle 3A, the liquid supply pipe 31A, and the support shaft 73 between the processing position and the standby position. The processing position is a position close to the substrate holding unit 2, and the standby position is a position vertically above the processing position. The shielding plate lift driving unit 75 includes, for example, a driving source such as a motor and a power transmission unit such as a ball screw mechanism. The shielding plate lift driving unit 75 is controlled by the control unit 90.

The shielding plate rotation driving unit 74 rotates the shielding plate 71 around the rotation axis Q1. The shielding plate rotation driving unit 74 may rotate the support shaft 73 and the shielding plate 71 about the rotation axis Q1. The shielding plate rotation driving unit 74 includes, for example, a driving source such as a motor. The shielding plate rotation driving unit 74 is controlled by the control unit 90.

An example of the operation of the processing unit 1B is similar to that in FIG. 17. Here, specific operations in steps S31 to S34 are different from the operation of the processing unit 1A according to the second embodiment.

For example, in step S31 (holding step), the shielding plate 71 receives and holds the substrate W from the center robot 122. Specifically, the center robot 122 moves a hand to a position where the center of the substrate W placed on the hand coincides with the rotation axis Q1. Then, the shielding plate lift driving unit 75 lowers the shielding plate 71 to the receiving position where the plurality of chuck pins 72 is horizontally adjacent to the substrate W on the hand. In this state, the processing unit 1B moves the plurality of chuck pins 72 to the holding position. Thus, the plurality of chuck pins 72 holds the substrate W. Then, the center robot 122 retracts the hand from the chamber 10. Next, the shielding plate lift driving unit 75 lowers the shielding plate 71 to the processing position. Thus, the substrate W held by the shielding plate 71 is brought close to the spin base 21. That is, the distance between the substrate W and the spin base 21 is narrowed. The processing position is a position where the substrate holding unit 2 can hold the substrate W by the chuck pins 22 of the substrate holding unit 2 moving to the holding position.

Next, in step S32 (rotation start step), the rotation driving unit 23 and the shielding plate rotation driving unit 74 start to rotate the spin base 21 and the shielding plate 71 around the rotation axis Q1, respectively. The rotation directions of the spin base 21 and the shielding plate 71 are, for example, the same, and the rotation driving unit 23 and the shielding plate rotation driving unit 74 rotate the spin base 21 and the shielding plate 71, for example, synchronously. Since the chuck pin 22 located at the release position is located radially outward from the chuck pin 72 located at the holding position, even if the rotation speeds or the rotation directions of the spin base 21 and the shielding plate 71 are different, the processing unit 1B can rotate the shielding plate 71 and the spin base 21 while avoiding the collision of the chuck pin 22 and the chuck pin 72.

Next, in step S33 (pre-wet step), the processing unit 1B supplies the rinse liquid to the substrate W to fill the first space between the opposing surface 71a of the shielding plate 71 and the main surface Wa of the substrate W with the rinse liquid. Here, the control unit 90 opens the valve 32A, the rinse valve 44A, the valve 32B, and the rinse valve 44B. Thus, the rinse liquid is dispensed in a continuous flow state from the nozzle 3A toward the main surface Wa of the substrate W, and the rinse liquid is dispensed in a continuous flow state from the nozzle 3B toward the main surface Wb of the substrate W.

The rinse liquid dispensed from the nozzle 3A is deposited on the central portion of the main surface Wa of the substrate W, receives a centrifugal force accompanying the rotation of the substrate W, flows radially outward, and scatters (or flows down) outward from the peripheral edge of the substrate W. Here, since the interval between the opposing surface 71a of the shielding plate 71 and the main surface Wa of the substrate W is narrow, the first space between the opposing surface 71a and the main surface Wa is filled with the rinse liquid. That is, the first space between the opposing surface 71a and the main surface Wa is rendered liquid-tight by the rinse liquid. In other words, the interval between the opposing surface 71a and the main surface Wa and the flow rate of the rinse liquid from the nozzle 3A are set to the extent that the liquid-tight state of the first space can be realized. Since the interval between the opposing surface 71a and the main surface Wa is narrow, it can be said that the rinse liquid filled in the first space forms a liquid film.

The rinse liquid dispensed from the nozzle 3B is deposited on the central portion of the main surface Wb of the substrate W, receives a centrifugal force accompanying the rotation of the substrate W, flows radially outward, and scatters (or flows down) outward from the peripheral edge of the substrate W. Here, since the interval between the main surface Wb of the substrate W and the spin base 21 is narrow, the rinse liquid is filled in the second space between the substrate W and the spin base 21. That is, the second space between the substrate W and the spin base 21 is rendered liquid-tight by the rinse liquid. In other words, the interval between the substrate W and the spin base 21 and the flow rate of the rinse liquid from the nozzle 3B are set to the extent that the liquid-tight state of the second space can be realized. It can be said that since the interval between the main surface Wa of the substrate W and the upper surface of the spin base 21 is narrow, the rinse liquid filled in the second space also forms a liquid film.

In step S33, the rotation speeds of the shielding plate 71 and the spin base 21 may be different from each other, and the rotation directions of the shielding plate 71 and the spin base 21 may be opposite to each other. Thus, the liquid film of the rinse liquid can be stirred. Therefore, even if air bubbles are present in the liquid film of the rinse liquid, the air bubbles can be efficiently crushed.

When the first space and the second space are sufficiently filled with the rinse liquid, the processing unit 1B stops the supply of the rinse liquid. As a specific example, when a predetermined pre-time has elapsed since the start of the supply of the rinse liquid, the control unit 90 executes step S34.

In step S34 (chemical liquid processing step), the processing unit 1B supplies the chemical liquid to the substrate W to fill the first space between the opposing surface 71a of the shielding plate 71 and the main surface Wa of the substrate W with the chemical liquid. Here, the control unit 90 closes the rinse valve 44A and the rinse valve 44B, and opens the valve 32A, the chemical liquid valve 43A, the valve 32B, and the chemical liquid valve 43B. Thus, the chemical liquid is dispensed from the nozzle 3A toward the main surface Wa of the substrate W, and the chemical liquid is dispensed from the nozzle 3B toward the main surface Wb of the substrate W. Therefore, while the first space between the shielding plate 71 and the substrate W is filled with the chemical liquid, the second space between the substrate W and the spin base 21 is filled with the chemical liquid. That is, while the liquid film of the chemical liquid is formed in the first space, the liquid film of the chemical liquid is also formed in the second space.

Due to the supply of the chemical liquid, the processing liquid in the first space and the second space is replaced from the rinse liquid with the chemical liquid. Similarly to the first embodiment, since the chemical liquid can spread on the main surface Wa more uniformly from the initial stage of step S34, the rinse liquid can be replaced with the chemical liquid more uniformly. Therefore, the chemical liquid starts to act more uniformly on the main surface Wa of the substrate W. In other words, it is possible to reduce the variation in the distribution on the main surface Wa at the start timing at which the chemical liquid starts to act at each position on the main surface Wa of the substrate W.

Here, the rotation speeds of the shielding plate 71 and the spin base 21 may be temporally changed so as to be different from each other, or the rotation directions of the shielding plate 71 and the spin base 21 may be alternately switched. Thus, the relative rotation state between the shielding plate 71 and the spin base 21 changes with time. Therefore, the liquid film of the chemical liquid in the second space between the main surface Wb of the substrate W held by the shielding plate 71 and the spin base 21 can be effectively stirred. Therefore, even if air bubbles exist in the liquid film of the chemical liquid in the second space, the air bubbles can be efficiently crushed.

Next, the processing unit 1B transfers the substrate W from the shielding plate 71 to the substrate holding unit 2. Specifically, first, the control unit 90 closes the chemical liquid valve 43B. Thus, the liquid-tight state of the second space between the main surface Wb of the substrate W and the spin base 21 is released. Then, the control unit 90 stops the rotation of the shielding plate 71 and the substrate holding unit 2. At this time, the control unit 90 stops the rotation such that the plurality of chuck pins 72 of the shielding plate 71 and the plurality of chuck pins 22 of the substrate holding unit 2 are positioned differently in the circumferential direction. Next, the processing unit 1B moves the plurality of chuck pins 22 of the substrate holding unit 2 to the respective holding positions, and then moves the plurality of chuck pins 72 of the shielding plate 71 to the respective release positions. Thus, the substrate W is transferred from the shielding plate 71 to the substrate holding unit 2.

Next, the processing unit 1B rotates the shielding plate 71 and the spin base 21 of the substrate holding unit 2 again, while the control unit 90 opens the chemical liquid valve 43B. Thus, the second space is again in the liquid-tight state.

Here, the rotation speeds of the shielding plate 71 and the spin base 21 may be temporally changed so as to be different from each other, or the rotation directions of the shielding plate 71 and the spin base 21 may be alternately switched. Thus, since the relative rotation state between the shielding plate 71 and the spin base 21 changes with time, the liquid film of the chemical liquid in the first space between the opposing surface 71a of the shielding plate 71 and the main surface Wa of the substrate W held by the substrate holding unit 2 can be effectively stirred. Therefore, even if air bubbles exist in the liquid film of the chemical liquid in the first space, the air bubbles can be efficiently crushed.

When the substrate W is sufficiently processed with the chemical liquid, the processing unit 1B stops the supply of the chemical liquid. As a specific example, when a predetermined chemical liquid processing time has elapsed since the start of the supply of the chemical liquid, the control unit 90 executes step S35.

In step S35 (post-wet step), the processing unit 1B supplies the rinse liquid to the substrate W to fill the first space between the opposing surface 71a of the shielding plate 71 and the main surface Wa of the substrate W with the rinse liquid. Here, the control unit 90 closes the chemical liquid valve 43A and the chemical liquid valve 43B, and opens the valve 32A, the rinse valve 44A, the valve 32B, and the rinse valve 44B. Thus, the rinse liquid is dispensed from the nozzle 3A toward the main surface Wa of the substrate W, and the rinse liquid is dispensed from the nozzle 3B toward the main surface Wb of the substrate W. The rinse liquid pushes the chemical liquid in the first space between the shielding plate 71 and the substrate W to flow radially outward and pushes the chemical liquid in the second space between the substrate W and the spin base 21 to flow radially outward. Thus, the liquid film of the rinse liquid is formed in the first space, while the liquid film of the rinse liquid is also formed in the second space.

Since the substrate W is held by the substrate holding unit 2, the rinse liquid in the first space can be stirred by relative rotation between the shielding plate 71 and the substrate W. When the rotation state of the shielding plate 71 and the substrate W is temporally changed, the rinse liquid in the first space can be more effectively stirred. Thus, the liquid in the first space can be more effectively replaced from the chemical liquid with the rinse liquid.

Next, the processing unit 1B transfers the substrate W from the substrate holding unit 2 to the shielding plate 71. This transfer is performed, for example, by displacing the chuck pin 22 and the chuck pin 72 in a state where the rinse valve 44B is closed. Then, the control unit 90 opens the rinse valve 44B to dispense the rinse liquid from the nozzle 3B again. Thus, the second space is again in the liquid-tight state.

Since the substrate W is held by the shielding plate 71, the rinse liquid in the second space can be stirred by relative rotation between the substrate W and the spin base 21. When the rotation state of the substrate W and the spin base 21 is temporally changed, the rinse liquid in the second space can be more effectively stirred. Thus, the liquid in the second space can be more effectively replaced from the chemical liquid with the rinse liquid.

When the replacement of the chemical liquid with the rinse liquid is sufficiently performed, the processing unit 1B stops the supply of the rinse liquid. As a specific example, when a predetermined post-time has elapsed since the start of rinse liquid supply, the control unit 90 closes the valve 32A, the rinse valve 44A, the valve 32B, and the rinse valve 44B.

Next, in step S36 (drying step), the processing unit 1B dries the substrate W. As a specific example, the substrate holding unit 2 further increases the rotation speed of the substrate W (so-called spin drying). The rotation speed of the substrate W may be set to, for example, more than 1200 rpm, 1500 rpm or more, or 2000 rpm or more. Since the rotation speed of the substrate W is higher than the rotation speed of the substrate W in steps S33 to S35, the amount of the processing liquid scattered from the peripheral edge of the substrate W can be increased. In addition, the evaporation of the processing liquid of the substrate W can be promoted by the airflow. Therefore, the substrate W can be dried more quickly.

Note that the processing unit 1B may include a first gas supply unit (not illustrated) that dispenses an inert gas from a first gas dispense port (not illustrated) formed on the opposing surface 71a of the shielding plate 71 toward the main surface Wa of the substrate W, and a second gas supply unit (not illustrated) that dispenses an inert gas from a second gas dispense port (not illustrated) formed on the upper surface of the spin base 21 toward the main surface Wb of the substrate W. In this case, the first gas supply unit and the second gas supply unit may dispense the inert gas in step S36. According to this, drying of the substrate W can be promoted.

When the substrate W is sufficiently dried, the processing unit 1 stops the rotation of the substrate W. For example, when a predetermined drying time has elapsed since the increase in the rotation speed, the substrate holding unit 2 stops the rotation of the substrate W.

Next, in step S37 (holding releasing step), the processing unit 1B releases the holding of the substrate W. Specifically, first, the shielding plate lift driving unit 75 raises the shielding plate 71 to a handover position, and the center robot 122 moves the hand to the handover position. Then, the processing unit 1B displaces the plurality of chuck pins 72 from the respective holding positions to the release positions, and transfers the substrate W to the hand of the center robot 122. Then, the center robot 122 retracts the hand from the chamber 10 to carry out the substrate W from the processing unit 1B.

As described above, the processing unit 1B can perform various types of processing on the substrate W whose main surface Wa has an uneven shape formed by the plurality of dies D0.

Also in the third embodiment, in step S33 immediately before step S34, the liquid film of the rinse liquid is formed on the main surface Wa of the substrate W (that is, the first space). Therefore, at the start of step S34, the chemical liquid from the first nozzle 3 is supplied to the liquid film of the rinse liquid. Therefore, the chemical liquid is not directly deposited on the corner portion of the die D0, and flows together with the rinse liquid on the main surface Wa of the substrate W. Therefore, the chemical liquid can spread with high fluidity from the initial stage of step S34. Therefore, the replacement of the rinse liquid with the chemical liquid is more uniformly performed. That is, variations in start timing can be reduced. In other words, the processing unit 1B can more uniformly start the chemical liquid processing on the main surface Wa (for example, the die D0) of the substrate W.

Moreover, the processing unit 1B supplies the chemical liquid in a state where the first space between the shielding plate 71 and the substrate W is filled with the rinse liquid. That is, in a state where the dispense port 3Aa of the nozzle 3A is in contact with the liquid film of the rinse liquid, the chemical liquid is dispensed from the dispense port 3Aa into the liquid film of the rinse liquid. Therefore, since the chemical liquid spreads in the liquid film of the rinse liquid, it is possible to avoid liquid splashing of the chemical liquid due to the irregularities of the main surface Wa of the substrate W. Therefore, the group of droplets hardly scatters outside the guard 61.

### Fourth Embodiment

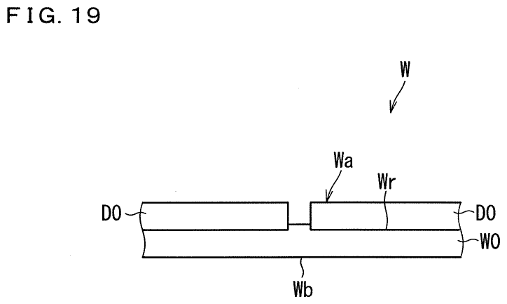

In the fourth embodiment, an example of another type of the substrate W will be described. FIG. 19 is a cross-sectional view schematically illustrating an example of a part of the configuration of the substrate W. In the example of FIG. 19, a concave portion Wr is formed on a surface of the support substrate W0 of the substrate W on which the die D0 is provided. A part of the die D0 is inserted into the concave portion Wr. The concave portion Wr has a rectangular shape similar to that of the die D0 in plan view. The depth of the die D0 may be set to, for example, ⅕ or less of the thickness of the die D0, or may be set to 1/10 or less of the thickness of the die D0. As a specific example, the depth of the concave portion Wr can be set to about 15 μm. In the support substrate W0, a plurality of concave portions Wr is formed corresponding to the plurality of dies D0. The plurality of concave portions Wr is arranged in a matrix, for example. For example, the concave portions Wr are arranged similarly to the dies D0 in FIG. 2.

The substrate processing apparatus 100 and the substrate processing method according to the first to third embodiments are also applicable to the substrate W illustrated in FIG. 19. In addition, the substrate processing apparatus 100 and the substrate processing method according to the first to third embodiments may be applied to the support substrate W0. That is, the substrate processing apparatus 100 and the substrate processing method according to any one of the first to third embodiments may be applied to the support substrate W0 before the dies D0 are arranged.

As described above, the substrate processing method has been described in detail, but the above description is an example in all aspects, and the disclosure thereof is not limited thereto. In addition, the various modifications described above can be applied in combination as long as they do not contradict each other. It is understood that many modifications which have not been illustrated can be assumed without departing from the scope of the present disclosure.

For example, in FIGS. 5, 16, and 18, although the chemical liquid and the rinse liquid are dispensed from the common first nozzle 3, the processing unit 1 may individually include the first nozzle 3 for the chemical liquid and the first nozzle 3 for the rinse liquid. In this case, the shapes of the first nozzle 3 for the chemical liquid and the first nozzle 3 for the rinse liquid may be the same. More specifically, the shape, size, number, and pitch of each of the plurality of dispense ports 3a may be common between the first nozzle 3 for the chemical liquid and the first nozzle 3 for the rinse liquid.

Although the first chemical liquid, the second chemical liquid, and the rinse liquid are dispensed from the common first nozzle 3 in the example of FIG. 14, the processing unit 1 may individually include the first nozzle 3 for the first chemical liquid and the rinse liquid and the first nozzle 3 for the second chemical liquid and the rinse liquid. Furthermore, the processing unit 1 may individually include the first nozzle 3 for the first chemical liquid, the first nozzle 3 for the second chemical liquid, and the first nozzle 3 for the rinse liquid. The shapes of these first nozzles 3 may be the same as each other.

In the above-described specific examples of the first embodiment and the second embodiment, the first nozzle 3 is a nozzle having a plurality of dispense ports 3a arranged in a line, but the first nozzle 3 may also be a flat nozzle in which the plurality of dispense ports 3a is two-dimensionally dispersedly arranged in plan view. The first nozzle 3 can supply the processing liquid to the main surface Wa of the substrate W in a wider range. The first nozzle 3 may also be referred to as full-surface nozzle.

The rinse liquid in step S3 (pre-wet step) may be a different type of rinse liquid from the rinse liquid in step S5 (post-wet step).

In the third embodiment, the second space between the substrate W and the spin base 21 is also in the liquid-tight state of the processing liquid, but the present invention is not necessarily limited thereto. In steps S33 to S35, the nozzle 3B may not dispense the processing liquid. In this case, the nozzle 3B may not be provided. In the third embodiment, the shielding plate 71 may not have a function of holding the substrate W. That is, the plurality of chuck pins 72 may not be provided. In this case, the substrate holding unit 2 continues holding the substrate W in steps S33 to S35.

### EXPLANATION OF REFERENCE SIGNS

3, 3A, 3B: first nozzle
3a, 3Aa: dispense port
71: shielding plate
71a: opposing surface
D0: die
L1: rinse liquid
L2: chemical liquid
S1, S11: holding step
S3, S13, S17: pre-wet step, pre-paddle step
S33: pre-wet step
S34: chemical liquid processing step
S35: post-wet step
S4, S14, S18: chemical liquid processing step, chemical liquid paddle step
S5, S15, S19: post-wet step, post-paddle step
S6, S16, S20: replacement promotion step
S7, S21: drying step
T: chemical liquid processing time
T1: replacement time
T2: actual processing time
W: substrate
Wa: main surface
ΔT: unit time

1. A substrate processing method comprising:
holding a substrate having a plurality of dies on a main surface;
supplying a rinse liquid to said main surface of said substrate while rotating said substrate at a rotation speed at which said rinse liquid covers said plurality of dies; and
supplying a chemical liquid from a first nozzle toward said main surface of said substrate while rotating said substrate at a rotation speed at which said chemical liquid covers said plurality of dies after supplying said rinse liquid.

2. The substrate processing method according to claim 1, wherein
said substrate is held in a posture in which said main surface is directed upward,
a liquid film of said rinse liquid covering said plurality of dies is maintained on said main surface of said substrate in supplying said rinse liquid, and
a liquid film of said chemical liquid covering said plurality of dies is maintained on said main surface of said substrate in supplying said chemical liquid.

3. The substrate processing method according to claim 2, wherein in supplying said chemical liquid, said chemical liquid is dispensed from a plurality of dispense ports toward said main surface of said substrate while reciprocating said first nozzle having said plurality of dispense ports in a direction along said main surface of said substrate.

4. The substrate processing method according to claim 2, wherein in supplying said chemical liquid, said chemical liquid is continuously dispensed from said first nozzle even after replacing said rinse liquid on said main surface of said substrate with said chemical liquid for an actual processing time longer than a replacement time required for replacing said rinse liquid with said chemical liquid.

5. The substrate processing method according to claim 2, wherein a difference between a chemical liquid processing time for dispensing said chemical liquid from said first nozzle toward said main surface of said substrate and an integral multiple of a unit time required for one rotation of said substrate is ¼ or less of said unit time.

6. The substrate processing method according to claim 2, wherein in supplying said rinse liquid, said rinse liquid is dispensed from said first nozzle toward said main surface of said substrate.

7. The substrate processing method according to claim 2, further comprising:
dispensing said rinse liquid from said first nozzle toward said main surface of said substrate while rotating said substrate at a rotation speed at which said rinse liquid covers said plurality of dies after supplying said chemical liquid.

8. The substrate processing method according to claim 7, wherein a difference between a rotation speed of said substrate in supplying said chemical liquid and a rotation speed of said substrate in supplying said rinse liquid after supplying said chemical liquid is 50% or less of the rotation speed of said substrate in supplying said chemical liquid.

9. The substrate processing method according to claim 7, further comprising:
supplying said rinse liquid to said main surface of said substrate while rotating said substrate at a first rotation speed higher than a second rotation speed of said substrate in supplying said rinse liquid after supplying said chemical liquid, after supplying said rinse liquid and supplying said chemical liquid.

10. The substrate processing method according to claim 9, wherein in supplying said rinse liquid while rotating said substrate at said first rotation speed, said rinse liquid is dispensed from a second nozzle toward a central portion of said main surface of said substrate.

11. The substrate processing method according to claim 9, further comprising:
drying said substrate by rotating said substrate at a third rotation speed higher than said first rotation speed after supplying said rinse liquid while rotating said substrate at said first rotation speed.

12. The substrate processing method according to claim 9, wherein
one set of supplying said rinse liquid before supplying said chemical liquid, supplying said chemical liquid, supplying said rinse liquid while rotating at said second rotation speed, and supplying said rinse liquid while rotating at said first rotation speed is performed a plurality of times, and
in supplying said chemical liquid, different chemical liquids are supplied to said main surface of said substrate.

13. The substrate processing method according to claim 1, wherein said substrate is held in a posture with said main surface facing downward.

14. The substrate processing method according to claim 13, wherein
in supplying said chemical liquid, said chemical liquid is dispensed from a plurality of dispense ports of the first nozzle toward said main surface of said substrate, and
said first nozzle dispenses said chemical liquid toward a peripheral region of said main surface at a flow rate larger than a flow rate to a central region of said main surface of said substrate, said peripheral region being radially outward from said central region.

15. The substrate processing method according to claim 1, wherein
in supplying said rinse liquid, a space between an opposing surface of a shielding plate and said main surface is filled with said rinse liquid,
said opposing surface faces said main surface of said substrate, and
in supplying said chemical liquid, said space between said opposing surface and said main surface is filled with said chemical liquid.
